(19) United States
(12) Patent Application Publication
(10) Pub. No.: US 2023/0104394 A1
(43) Pub. Date: Apr. 6, 2023

(54) ELECTROLUMINESCENT DEVICE AND DISPLAY DEVICE INCLUDING THE SAME

(71) Applicant: Samsung Electronics Co., Ltd., Suwon-si (KR)

(72) Inventors: Heejae LEE, Suwon-si (KR); Dae-Hee LEE, Suwon-si (KR); Oul CHO, Suwon-si (KR); Taehyung KIM, Suwon-si (KR); Eun Joo JANG, Suwon-si (KR); Hyo Sook JANG, Suwon-si (KR)

(21) Appl. No.: 17/956,956

(22) Filed: Sep. 30, 2022

(30) Foreign Application Priority Data
Oct. 1, 2021 (KR) 10-2021-0131175

(51) Int. Cl. H01L 51/50

(52) U.S. Cl. CPC H01L 51/502; H01L 51/5072; H01L 2251/303

(57) ABSTRACT

An electroluminescent device including a first electrode and a second electrode spaced apart from each other (e.g., each electrode having a surface opposite the other), and a light emitting layer disposed between the first electrode and the second electrode, and an electron transport layer disposed between the light emitting layer and the second electrode, wherein the light emitting layer includes semiconductor nanoparticles, wherein the electron transport layer includes a plurality of zinc oxide nanoparticles, and wherein the electron transport layer further includes an alkali metal and a halogen.

### CROSS-REFERENCE TO RELATED APPLICATION

This application claims priority to Korean Patent Application No. 10-2021-0131175 filed in the Korean Intellectual Property Office on Oct. 1, 2021, and all the benefits accruing therefrom under 35 U.S.C. § 119, the content of which in its entirety is herein incorporated by reference.

### BACKGROUND

### 1. Field

The present disclosure relates to semiconductor nanoparticles and a device including the same.

### 2. Description of the Related Art

A semiconductor nanoparticle (e.g., a semiconductor nanocrystal particle) having a nanometer size may emit light. For example, a semiconductor nanoparticle including a semiconductor nanocrystal may exhibit a quantum confinement effect, and thereby, demonstrate luminance properties. For example, light emission from the semiconductor nanoparticle may occur when an electron in an excited state resulting from light excitation or an applied voltage transitions from a conduction band to a valence band. The semiconductor particle may be configured to emit light of a desired wavelength region by adjusting a size of the semiconductor nanoparticle, a composition of the semiconductor nanoparticle, or a combination thereof.

Semiconductor nanoparticles may be used in an electroluminescent device (e.g., an electroluminescent light emitting device) and a display device including the same.

### SUMMARY

An embodiment provides a luminescent device that emits light, for example, by applying a voltage to nanostructures (e.g., nanoparticles such as semiconductor nanoparticles).

An embodiment provides a display device (e.g., a quantum dot (QD)-light emitting diode (LED) display) that includes a light emitting material having nanostructures (e.g., nanoparticle such as semiconductor nanoparticle) in a configuration of a blue pixel, a red pixel, a green pixel, or a combination thereof.

An embodiment provides an electroluminescent device including a first electrode and a second electrode spaced apart from each other (e.g., each electrode having a surface opposite the other), and a light emitting layer disposed between the first electrode and the second electrode, and an electron transport layer disposed between the light emitting layer and the second electrode, wherein the light emitting layer includes a plurality of semiconductor nanoparticles, and the electron transport layer includes a plurality of zinc oxide nanoparticles, and wherein the electron transport layer further includes an alkali metal and a halogen.

The electron transport layer may include an alkali metal halide.

In an embodiment, the semiconductor nanoparticles may not include cadmium, lead, mercury, or a combination thereof.

The electroluminescent device may further include a hole auxiliary layer between the light emitting layer and the first electrode. The hole auxiliary layer may include a hole transport layer (e.g., including an organic compound), a hole injection layer, or a combination thereof.

The semiconductor nanoparticles may include a first semiconductor nanocrystal including zinc, selenium, and tellurium, and a second semiconductor nanocrystal including a zinc chalcogenide and being different from the first semiconductor nanocrystal.

The semiconductor nanoparticles may include a first semiconductor nanocrystal including indium, phosphorus, and optionally further including zinc and a second semiconductor nanocrystal including a zinc chalcogenide and different from the first semiconductor nanocrystal.

An average size of the semiconductor nanoparticles may be greater than or equal to about 4 nanometers (nm), greater than or equal to about 5 nm, greater than or equal to about 7 nm, greater than or equal to about 8 nm, greater than or equal to about 9 nm, or greater than or equal to about 10 nm. An average size of the semiconductor nanoparticles may be less than or equal to about 30 nm, less than or equal to about 20 nm, less than or equal to about 15 nm, less than or equal to about 12 nm, or less than or equal to about 10 nm.

The semiconductor nanoparticles may include a core including the first semiconductor nanocrystal and a shell disposed on the core and including the second semiconductor nanocrystal.

The electron transport layer may be adjacent to (or disposed directly on) the light emitting layer.

The electron transport layer may be directly adjacent to (or disposed directly under) the second electrode.

The zinc oxide nanoparticles may include an additional metal including Mg, Ca, Zr, W, Li, Ti, Y, Al, or a combination thereof.

The zinc oxide nanoparticles may include a compound represented by Zn₁₋ₓMₓO, wherein, M is Mg, Ca, Zr, Co, W, Li, Ti, Y, Al, or a combination thereof, and 0≤x≤0.5. The x may be greater than or equal to about 0.01, greater than or equal to about 0.03, greater than or equal to about 0.05, greater than or equal to about 0.1, or greater than or equal to about 0.15. The x may be less than or equal to about 0.45, or less than or equal to about 0.4. An average size of the zinc oxide nanoparticles may be greater than or equal to about 1 nm, or greater than or equal to about 3 nm. An average size of the zinc oxide nanoparticles may be less than or equal to about 10 nm, or less than or equal to about 8 nm.

The alkali metal may include lithium, sodium, potassium, rubidium, cesium, or a combination thereof. The alkali metal may be in a form of a cation. The halogen may include chlorine, fluorine, bromine, iodine, or a combination thereof. The halogen may be in an anion (e.g., a halide), In an embodiment, the alkali metal may include cesium, rubidium, or a combination thereof, and the halogen may include chlorine (e.g., chloride). The electron transport layer may include cesium, rubidium, and chlorine.

In an electron transport layer, an amount of the halogen per one mole of the alkali metal may be greater than or equal to about 0.1 moles, greater than or equal to about 0.3 moles, greater than or equal to about 0.5 moles, greater than or equal to about 0.8 moles, or greater than or equal to about 1 mole. The amount of the halogen per one mole of the alkali metal may be less than or equal to about 10 moles, less than or equal to about 5 moles, less than or equal to about 3 moles, less than or equal to about 2.5 moles, less than or equal to about 2 moles, less than or equal to about 1.5 moles, less than or equal to about 1 mole, less than or equal to about 0.5 moles, or less than or equal to about 0.1 moles.

In the electron transport layer, an amount of halogen (e.g., chlorine) may be, per one mole of zinc, greater than or equal to about 0.005 moles, greater than or equal to about 0.009 moles, greater than or equal to about 0.01 moles, greater than or equal to about 0.013 moles, or greater than or equal to about 0.015 moles.

In the electron transport layer, an amount of halogen (e.g., chlorine) may be, per one mole of zinc, less than or equal to about 0.5 moles, less than or equal to about 0.3 moles, less than or equal to about 0.1 moles, less than or equal to about 0.05 moles, or less than or equal to about 0.03 moles.

In the electron transport layer, an amount of an alkali metal (e.g., cesium) may be, per one mole of zinc, greater than or equal to about 0.005 moles, greater than or equal to about 0.009 moles, greater than or equal to about 0.01 moles, greater than or equal to about 0.013 moles, greater than or equal to about 0.015 moles, greater than or equal to about 0.017 moles, or greater than or equal to about 0.02 moles.

In the electron transport layer, an amount of an alkali metal (e.g., cesium) may be, per one mole of zinc, 0.5 moles, less than or equal to about 0.3 moles, less than or equal to about 0.1 moles, less than or equal to about 0.07 moles, less than or equal to about 0.05 moles, or less than or equal to about 0.03 moles. The electron transport layer may further include an additional metal (e.g., magnesium) and an amount of halogen may be, per one mole of the additional metal (e.g., magnesium), greater than or equal to about 0.05 moles, greater than or equal to about 0.07 moles, greater than or equal to about 0.1 moles, or greater than or equal to about 0.12 moles.

The electron transport layer may further include an additional metal (e.g., magnesium) and an amount of halogen may be, per one mole of the additional metal (e.g., magnesium), less than or equal to about 1 mole, less than or equal to about 0.5 moles, less than or equal to about 0.3 moles, or less than or equal to about 0.2 moles.

The electron transport layer may further include an additional metal (e.g., magnesium) and an amount of an alkali metal may be, per one mole of the additional metal (e.g., magnesium), greater than or equal to about 0.05 moles, greater than or equal to about 0.07 moles, greater than or equal to about 0.1 moles, greater than or equal to about 0.12 moles, greater than or equal to about 0.15 moles.

The electron transport layer may further include an additional metal (e.g., magnesium) and an amount of an alkali metal may be, per one mole of the additional metal (e.g., magnesium), less than or equal to about 1 mole, less than or equal to about 0.5 moles, less than or equal to about 0.3 moles, or less than or equal to about 0.2 moles.

A thickness of the electron transport layer may be greater than or equal to about 5 nm. A thickness of the electron transport layer may be less than or equal to about 70 nm.

The electron transport layer may include a first surface facing the light emitting layer and a second surface opposite to the first surface.

The electron transport layer may include a first portion in a thickness direction of the electron transport layer, the first portion including the first surface, a second portion in the thickness direction of the electron transport layer, the second portion including the second surface, and optionally a third portion between the first portion and the second portion in the thickness direction of the electron transport layer.

A total amount of the alkali metal and the halogen in the first portion of electron transport layer may be greater than a total amount of the alkali metal and the halogen in the second portion of electron transport layer.

The electron transport layer may include a first layer including the first surface and a second layer including the second surface.

A thickness of the first layer may be greater than or equal to about 1 nm, or greater than or equal to about 3 nm.

A thickness of the first layer may be less than or equal to about 10 nm, or less than or equal to about 5 nm.

A thickness of the second layer may be greater than or equal to about 4 nm, or greater than or equal to about 10 nm.

A thickness of the electron transport layer may be less than or equal to about 40 nm, less than or equal to about 20 nm.

A zinc oxide nanoparticle of the first layer may further include Mg, Ca, Zr, W, Li, Ti, Y, Al, or a combination thereof.

A zinc oxide nanoparticle of the first layer may further include or may not include Mg, Ca, Zr, W, Li, Ti, Y, Al, or a combination thereof.

The second portion or the second layer may include or may not include the alkali metal. In an embodiment, the second portion or the second layer may not include the halogen. In an embodiment, the second portion or the second layer may not include the alkali metal and the halogen. The first portion or the first layer may further include an alkali metal that is not included, e.g., present, in the second portion or the second layer.

In an embodiment, a mole ratio of the halogen to the zinc in the electron transport layer may be greater than or equal to about 0.01:1, greater than or equal to about 0.05:1, or greater than or equal to about 0.1:1, for example, as determined in a transmission electron microscopy analysis.

The mole ratio of the halogen to the zinc in the electron transport layer may be less than or equal to about 0.9:1, or less than or equal to about 0.5:1.

In an embodiment, the mole ratio of the alkali metal to the zinc in the electron transport layer may be greater than or equal to about 0.01:1, greater than or equal to about 0.02:1, greater than or equal to about 0.1:1 (for example, as determined in a transmission electron microscopy analysis).

The mole ratio of the alkali metal to the zinc in the electron transport layer may be less than or equal to about 0.9:1, less than or equal to about 0.5:1.

The electron transport layer may further include magnesium and, for example, as determined in a transmission electron microscopy analysis, a mole ratio of the halogen to the magnesium may be greater than or equal to about 0.15:1, greater than or equal to about 0.3:1, greater than or equal to about 0.5:1, or greater than or equal to about 1:1.

The electron transport layer may further include magnesium and, for example, as determined in a transmission electron microscopy analysis, a mole ratio of the halogen to the magnesium may be less than or equal to about 2:1, less than or equal to about 1.5:1, less than or equal to about 1:1, less than or equal to about 0.5:1, or less than or equal to about 0.2:1.

In a graph of external quantum efficiency versus luminance of the electroluminescent device, an external quantum efficiency at a luminance of half the maximum luminance may be less than or equal to about 0.7 times, e.g., less than or equal to about two thirds (⅔) or less than or equal to about one half (½), of a maximum external quantum efficiency.

A brightness of the electroluminescent device may decrease to 50% of an initial brightness of the electroluminescent device after greater than or equal to about 480 hours, greater than or equal to about 500 hours, or greater than or equal to about 600 hours, as measured by operating the device, e.g., when operated, at a predetermined luminance (e.g., about 650 candelas per square meter (nit)). A brightness of the electroluminescent device may decrease to 90% of an initial brightness of the electroluminescent device after greater than or equal to about 10 hours, greater than or equal to about 20 hours, or greater than or equal to about 50 hours, as measured by operating the device at a predetermined luminance (e.g., about 650 nit).

The electron transporting layer may be adjacent to (e.g., disposed directly on) a second electrode and, for example in a cross-section analysis of the electroluminescent device, an interface roughness between the electron transporting layer and the second electrode may be greater than or equal to about 5 nm, greater than or equal to about 6 nm, greater than or equal to about 10 nm, or greater than or equal to about 12 nm and less than or equal to about 100 nm, or less than or equal to about 50 nm.

The electroluminescent device may be configured to emit red light, for example, on an application of a voltage.

The electroluminescent device may be configured to emit green light, for example, on an application of a voltage.

The electroluminescent device may be configured to emit blue light, for example, on an application of a voltage.

The electroluminescent device may exhibit a maximum external quantum efficiency of greater than or equal to about 6%, or greater than or equal to about 11%, and less than or equal to about 40%.

The electroluminescent device may exhibit a maximum luminance of greater than or equal to about 60,000 nit (candela per square meter or cd/m²), greater than or equal to about 80,000 nit, greater than or equal to about 100,000 nit and less than or equal to about 5,000,000 nit.

In an embodiment, a display device or an electronic device may include the electroluminescent device.

The display device or an electronic device may include (or may be) a handheld terminal, a monitor, a notebook computer, a television, an electronic display board, a camera, a part for an automatic vehicle.

In an embodiment, an electron transport layer for an electroluminescent device includes zinc oxide nanoparticles including zinc, magnesium, and oxygen; an alkali metal including lithium, sodium, potassium, rubidium, cesium, or a combination thereof; and a halogen including chlorine, fluorine, bromine, iodine, or a combination thereof, wherein a mole ratio of the halogen to the zinc is greater than or equal to about 0.01:1 and less than or equal to about 0.9:1, a mole ratio of the alkali metal to the zinc is greater than or equal to about 0.01:1 and less than or equal to about 0.9:1, or a mole ratio of the halogen to the zinc is greater than or equal to about 0.01:1 and less than or equal to about 0.9:1 and a mole ratio of the alkali metal to the zinc is greater than or equal to about 0.01:1 and less than or equal to about 0.9:1.

According to an embodiment, the electroluminescent device may exhibit increased electroluminescent properties together with a desired or improved lifespan. According to an embodiment, the electroluminescent device may show a relatively increased external quantum efficiency together with a maximum luminance and address the deterioration issues at an interface between a light emitting layer and auxiliary layers (e.g., electron transport layer (ETL)).

### BRIEF DESCRIPTION OF THE DRAWINGS

The patent or application file contains at least one drawing executed in color. Copies of this patent or patent application publication with the color drawing(s) will be provided by the Office upon request and payment of the necessary fee.

The above and other advantages and features of this disclosure will become more apparent by describing in further detail exemplary embodiments thereof with reference to the accompanying drawings, in which:

FIG. 1 is a schematic cross-sectional view of a light-emitting device according to an embodiment.

FIG. 2 is a schematic cross-sectional view of a light-emitting device according to an embodiment.

FIG. 3 is a schematic cross-sectional view of a light-emitting device according to an embodiment.

FIG. 4 is a graph of current density (milliamperes per square centimeter (mA/cm²)) versus voltage (volts (V)) showing results of analyzing an electron only device (EOD) including an ion-blended electron transport layer.

FIG. 5 is a graph of photoluminescence (PL) intensity at 405 nm (arbitrary units (a.u.)) versus wavelength (nm) showing the results of a photoluminescent spectroscopy analysis for an electroluminescent device in Experimental Example 2.

FIG. 6 shows images of atomic force microscopy analysis of the electron transport layers of the electroluminescent devices prepared in Experimental Example 2.

FIG. 7 is a graph showing lifespan properties of the electroluminescent devices of Example 2 and Comparative Example 1, operated at a luminance of about 650 nit.

FIG. 8 is a graph of an external quantum efficiency (EQE)_(%) versus luminance (cd/m²) for the electroluminescent devices of Example 2 and Comparative Example 1.

FIG. 9 is a graph of voltage (V) versus operating time (hours) for the devices of Example 2 and Comparative Example 1 operated at a luminance of about 650 nit.

### DETAILED DESCRIPTION

Advantages and characteristics of this disclosure, and a method for achieving the same, will become evident referring to the following example embodiments together with the drawings attached hereto. However, the embodiments should not be construed as being limited to the embodiments set forth herein. Rather, these embodiments are provided so that this disclosure will be thorough and complete, and will fully convey the scope of the invention to those skilled in the art.

In order to clearly explain the present disclosure, parts irrelevant to the description are omitted, and the same reference numerals are assigned to the same or similar elements throughout the specification.

The size and thickness of each constituent element as shown in the drawings are indicated for better understanding and ease of description, and this disclosure is not necessarily limited to sizes or thicknesses shown. In the drawings, the thickness of layers, films, panels, regions, etc., are exaggerated for clarity. And in the drawings, for convenience of description, the thickness of some layers and regions are exaggerated. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion and does not necessarily mean “above”.

It will be understood that, although the terms “first,” “second,” “third” etc., may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as being limited to “a” or “an.” “Or” means “and/or.”

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As used herein, the term “cross-sectional phase” means a case in which a cross-section of a given object is cut, for example, in a substantially vertical direction and is viewed laterally.

Unless otherwise defined, all terms (including technical and scientific terms) used herein have the same meaning as commonly understood by one of ordinary skill in the art to which this disclosure belongs. It will be further understood that terms, such as those defined in commonly used, e.g., non-technical, dictionaries, should be interpreted as having a meaning that is consistent with their meaning in the context of the relevant art and the present disclosure, and will not be interpreted in an idealized or overly formal sense unless expressly so defined herein.

Hereinafter, values of a work function, a conduction band, or a lowest unoccupied molecular orbital (LUMO) (or valence band or highest occupied molecular orbital (HOMO)) energy level is expressed as an absolute value from a vacuum level. In addition, when the work function or the energy level is referred to be “deep,” “high” or “large,” the work function or the energy level has a large absolute value based on “0 eV” of the vacuum level, while when the work function or the energy level is referred to be “shallow,” “low,” or “small,” the work function or energy level has a small absolute value based on “0 electronvolts (eV)” of the vacuum level.

As used herein, the term “Group” may refer to a group of Periodic Table.

As used herein, “Group I” refers to Group IA and Group IB, and examples may include Li, Na, K, Rb, and Cs, but are not limited thereto.

As used herein, “Group II” refers to Group IIA and Group IIB, and examples of Group II metal may be Cd, Zn, Hg, and Mg, but are not limited thereto.

As used herein, “Group III” refers to Group IIIA and Group IIIB, and examples of Group IIIA metal may be Al, In, Ga, and TI, and examples of Group IIIB may be scandium, yttrium, or the like, but are not limited thereto.

As used herein, “Group IV” refers to Group IVA and Group IVB, and examples of a Group IVA metal may be Si, Ge, and Sn, and examples of Group IVB metal may be titanium, zirconium, hafnium, or the like, but are not limited thereto.

As used herein, “Group V” includes Group VA and includes nitrogen, phosphorus, arsenic, antimony, and bismuth, but is not limited thereto.

As used herein, “Group VI” includes Group VIA and includes sulfur, selenium, and tellurium, but is not limited thereto.

As used herein, “metal” includes a semi-metal such as Si.

As used herein, the average (value) may be mean or median. In an embodiment, the average (value) may be a mean average.

As used herein, a number of carbon atoms in a group or a molecule may be referred to as a subscript (e.g., C₆₋₅₀) or as C6 to C50.

As used herein, when a definition is not otherwise provided, “substituted” refers to replacement of a, e.g., at least one, hydrogen of a compound or the corresponding moiety by a C1 to C30 alkyl group, a C1 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon” or “hydrocarbon group” refers to a compound or a group including carbon and hydrogen (e.g., alkyl, alkenyl, alkynyl, or aryl group). The hydrocarbon group may be a monovalent group or a group having a valence or greater than one formed by removal of a, e.g., one or more, hydrogen atoms from alkane, alkene, alkyne, or arene. In the hydrocarbon or hydrocarbon group, a, e.g., at least one, methylene may be replaced by an oxide moiety, a carbonyl moiety, an ester moiety, —NH—, or a combination thereof. Unless otherwise stated to the contrary, the hydrocarbon compound or hydrocarbon group (alkyl, alkenyl, alkynyl, or aryl) may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl hexyl, etc.). Unless specified otherwise, an alkyl group has from 1 to 50 carbon atoms, or 1 to 18 carbon atoms, or 1 to 12 carbon atoms.

As used herein, when a definition is not otherwise provided, “alkenyl” refers to a linear or branched monovalent hydrocarbon group having a carbon-carbon double bond. Unless specified otherwise, an alkenyl group has from 2 to 50 carbon atoms, or 2 to 18 carbon atoms, or 2 to 12 carbon atoms.

As used herein, when a definition is not otherwise provided, “alkynyl” refers to a linear or branched monovalent hydrocarbon group having a carbon-carbon triple bond. Unless specified otherwise, an alkenyl group has from 2 to 50 carbon atoms, or 2 to 18 carbon atoms, or 2 to 12 carbon atoms.

As used herein, when a definition is not otherwise provided, “aryl” refers to a group formed by removal of a, e.g., at least one, hydrogen from an arene (e.g., a phenyl or naphthyl group). Unless specified otherwise, an aryl group has from 6 to 50 carbon atoms, or 6 to 18 carbon atoms, or 6 to 12 carbon atoms.

As used herein, when a definition is not otherwise provided, “hetero” refers to including 1 to 3 heteroatoms, e.g., N, O, S, Si, P, or a combination thereof.

As used herein, when a definition is not otherwise provided, “alkoxy” refers to an alkyl group linked to oxygen (e.g., alkyl-O—) for example, a methoxy group, an ethoxy group, or a sec-butyloxy group.

In an embodiment, the functional group may be “a hydroxy oxygen,” that is a deprotonated hydroxyl group, and may be formed as a ligand compound including a hydroxyl group interacts (coordinates) to a semiconductor nanoparticle or nanoparticle with the oxygen of the deprotonated hydroxyl group.

As used herein, when a definition is not otherwise provided, “amine” group is a group represented by —NRR (wherein R is each independently hydrogen, a C1-C12 alkyl group, a C7-C20 alkylarylene group, a C7-C20 arylalkylene group, or a C6-C18 aryl group.

As used herein, when a definition is not otherwise provided, “alkylene group” refers to a straight or branched saturated aliphatic hydrocarbon group having at least two valences and optionally substituted with a, e.g., at least one, substituent.

As used herein, when a definition is not otherwise provided, “arylene group” refers to a functional group having at least two valences obtained by removal of at least two hydrogens in an, e.g., at least one, aromatic ring, and optionally substituted with a, e.g., at least one, substituent.

As used herein, when a definition is not otherwise provided, “aliphatic group” or “aliphatic hydrocarbon” refers to a saturated or unsaturated linear or branched C1 to C30 group consisting of carbon and hydrogen, and “aromatic organic group” includes a C6 to C30 aryl group or a C2 to C30 heteroaryl group, and “alicyclic group” refers to a saturated or unsaturated C3 to C30 cyclic group consisting of carbon and hydrogen.

As used herein, the term “chalcogen” is inclusive of sulfur (S), selenium (Se), and tellurium (Te). In an embodiment, the term “chalcogen” may include or may not include oxygen (O).

As used herein, the upper and lower endpoints set forth for various values may be independently combined to provide a range.

As used herein, the expression “not including cadmium (or other harmful heavy metal)” may refer to the case in which a concentration of each of cadmium (or another heavy metal deemed harmful) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or about zero. In an embodiment, substantially no amount of cadmium (or other toxic heavy toxic metal) may be present or, if present, an amount of cadmium (or other heavy metal) may be less than or equal to a detection limit or as an impurity level of a given analysis tool (e.g., an inductively coupled plasma atomic emission spectroscopy).

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, ±5%, ±3%, or ±1% of the stated value.

As used herein, a nanostructure or a nanoparticle is a structure having a, e.g., at least one, region or characteristic dimension with a dimension of less than or equal to about 500 nm. In an embodiment, a dimension (or an average) of the nanostructure is less than or equal to about 300 nm, less than or equal to about 250 nm, less than or equal to about 150 nm, less than or equal to about 100 nm, less than or equal to about 50 nm, or less than or equal to about 30 nm. In an embodiment, the structure may have any suitable shape. The nanostructure may include a nanowire, a nanorod, a nanotube, a branched nanostructure, a nanotetrapod, a nanotripod, a nanobipod, a nanocrystal, a nanodot, a multi-pod type shape such as at least two pods, or the like and is not limited thereto. The nanostructure or the nanoparticle can be, e.g., substantially crystalline, substantially monocrystalline, polycrystalline (for example, at least partially) amorphous, or a combination thereof.

In an embodiment, a semiconductor nanostructure or a semiconductor nanoparticle may exhibit quantum confinement or exciton confinement. As used herein, the term “semiconductor nanostructure” or “semiconductor nanoparticle” is not limited in a shape thereof unless otherwise specified. A semiconductor nanostructure or a semiconductor nanoparticle may have a size smaller than a Bohr excitation diameter for a bulk crystal material having an identical composition and may exhibit a quantum confinement effect. The semiconductor nanostructure or the semiconductor nanoparticle may emit light corresponding to a bandgap energy thereof by controlling a size of a nanocrystal acting as an emission center.

As used herein, the term “T50” is a time (hours (hr)) for the brightness (e.g., luminance) of a given device to decrease to 50% of the initial brightness (100%) as, e.g., when, the given device is driven, e.g., operated, at a predetermined brightness (e.g., 650 nit).

As used herein, the term “T90(h)” is a time (hr) for the brightness (e.g., luminance) of a given device to decrease to 90% of the initial brightness (100%) as the given device is driven at a predetermined brightness (e.g., 650 nit).

As used herein, the phrase “external quantum efficiency (EQE)” is a ratio of the number of photons emitted from a light emitting diode (LED) to the number of electrons passing through the device, and can be a measurement as to how efficiently a given device converts electrons to photons and allows the photons to escape. The EQE can be determined by the following equation:

EQE=an efficiency of injection×a (solid-state) quantum yield×an efficiency of extraction.

wherein the efficiency of injection is a proportion of electrons passing through the device that are injected into the active region, the quantum yield is a proportion of all electron-hole recombination in the active region that are radiative and produce photons, the efficiency of extraction is a proportion of photons generated in the active region that escape from the given device.

As used herein, a maximum EQE is a greatest value of the EQE.

As used herein, a maximum luminance is a greatest value of the luminance a given device can achieve.

As used herein, the phrase quantum efficiency may be used interchangeably with a quantum yield. In an embodiment, the quantum efficiency may be a relative quantum yield or an absolute quantum yield, for example, which can be readily measured by any suitable, e.g., commercially available, equipment. The quantum efficiency (or quantum yield) may be measured in a solution state or a solid state (in a composite). In an embodiment, “quantum yield (or quantum efficiency)” may be a ratio of photons emitted to photons absorbed, e.g., by a nanostructure or population of nanostructures. In an embodiment, the quantum efficiency may be determined by any suitable method. For example, there may be two methods for measuring the fluorescence quantum yield or efficiency: the absolute method and the relative method.

The absolute method directly obtains the quantum yield by detecting all sample fluorescence through the use of an integrating sphere. In the relative method, the fluorescence intensity of a standard sample (e.g., a standard dye) may be compared with the fluorescence intensity of an unknown sample to calculate the quantum yield of the unknown sample. Coumarin 153, Coumarin 545, Rhodamine 101 inner salt, Anthracene, and Rhodamine 6G may be used as a standard dye, depending on the PL wavelengths thereof, but are not limited thereto.

Unless mentioned to the contrary, a numerical range recited herein includes any real number within the endpoints of the stated range and includes the endpoints thereof.

A bandgap energy of a semiconductor nanoparticle may vary with a size and a composition of a nanocrystal. For example, as a size of the semiconductor nanoparticle increases, the bandgap energy of the semiconductor nanoparticle may narrow, e.g., decrease, and the semiconductor nanoparticle may emit light of increased, e.g., having an increased, emission wavelength. A semiconductor nanocrystal may be used as a light emitting material in various fields such as a display device, an energy device, or a bio light emitting device.

A semiconductor nanoparticle electroluminescent device (hereinafter, also referred to as QD-LED) may emit light by applying a voltage and includes a semiconductor nanoparticle as a light emitting material. A QD-LED uses a different emission principle from an organic light emitting diode (OLED) using organic materials and realizes, e.g., displays, colors (red, green, blue) of greater purity and improved color reproducibility. A QD-LED may be used in a next generation display device. A method of producing the QD-LED may include a solution process, which may lower, e.g., reduce, a manufacturing cost. In addition, the semiconductor nanoparticles in the QD-LED is based on an inorganic material, contributing to realization of an increased stability. It is still desired to develop a technology improving a performance and a lifespan of a device.

Semiconductor nanoparticles exhibiting a desirable electroluminescent property may contain a harmful heavy metal such as cadmium (Cd), lead, mercury, or a combination thereof. Accordingly, it is desirable to provide an electroluminescent device or a display device having a light emitting layer substantially free of a harmful heavy metal.

In an embodiment, an electroluminescent device may be a luminescent type of electroluminescent device configured to emit a desired light by applying a voltage.

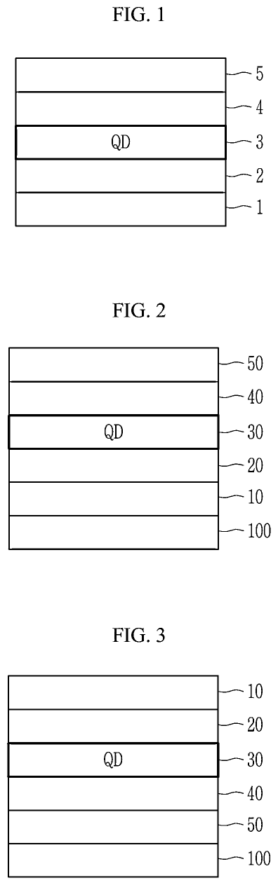

In an embodiment, an electroluminescent device includes a first electrode 1 and a second electrode 5 spaced apart each other (e.g., each having a surface opposite the other, i.e., each with a surface facing each other); and a light emitting layer 3 disposed between the first electrode 1 and the second electrode 5, and an electron transport layer 4 disposed between the light emitting layer 3 and the second electrode 5. In an embodiment, the electroluminescent device may further include a hole auxiliary layer 2 between the light emitting layer and the first electrode. The hole auxiliary layer may include a hole transport layer including an organic compound, a hole injection layer, or a combination thereof. See FIG. 1.

The first electrode may include an anode, and the second electrode may include a cathode. The first electrode may include a cathode and the second electrode may include an anode. In the electroluminescent device of an embodiment, the first electrode 10 or the second electrode 20 may be disposed on a (transparent) substrate. The transparent substrate may be a light extraction surface as depicted in FIG. 2 and FIG. 3. The light emitting layer may be disposed in a pixel of a display device described herein.

Referring to FIGS. 2 and 3, in an electroluminescent device of an embodiment, a light emitting layer 30 may be disposed between a first electrode (e.g., anode) 10 and a second electrode (e.g., cathode) 50. The cathode 50 may include an electron injection conductor. The anode 10 may include a hole injection conductor. The work functions of the electron/hole injection conductors included in the cathode and the anode may be appropriately adjusted and are not particularly limited. For example, the cathode may have a small work function and the anode may have a relatively large work function, or vice versa.

The electron/hole injection conductors may include a metal-based material (e.g., a metal, a metal compound, an alloy, or a combination thereof) (e.g., aluminum, magnesium, tungsten, nickel, cobalt, platinum, palladium, calcium, LiF, etc.), a metal oxide such as gallium indium oxide or indium tin oxide (ITO), or a conductive polymer (e.g., having a relatively high work function) such as polyethylene dioxythiophene, but are not limited thereto.

The first electrode, the second electrode, or a combination thereof may be a light-transmitting electrode or a transparent electrode. In an embodiment, both the first electrode and the second electrode may be a light-transmitting electrode. The first electrode, the second electrode, or a combination thereof may be patterned electrodes. The first electrode, the second electrode, or a combination thereof may be disposed on a (e.g., insulating) substrate 100. The substrate 100 may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and, for example, less than or equal to about 99%, or less than or equal to about 95%). The substrate 100 may include a region for a blue pixel, a region for a red pixel, a region for a green pixel, or a combination thereof. A thin film transistor may be disposed in each region of the substrate, and one of a source electrode and a drain electrode of the thin film transistor may be electrically connected to the first electrode or the second electrode.

The light-transmitting electrode may be disposed on a (e.g., insulating) transparent substrate. The substrate 100 may be a rigid or a flexible substrate. The substrate 100 may include a plastic or organic material such as a polymer, an inorganic material such as a glass, or a metal.

The light-transmitting electrode may be made of, for example, a transparent conductor such as indium tin oxide (ITO) or indium zinc oxide (IZO), gallium indium tin oxide, zinc indium tin oxide, titanium nitride, polyaniline, LiF/Mg:Ag, or the like, or a thin metal thin film of a single layer or a plurality of layers, but is not limited thereto. If one of the first electrode or the second electrode is an opaque electrode, the opaque electrode may be made of an opaque conductor such as aluminum (Al), a lithium-aluminum (Li:Al) alloy, a magnesium-silver (Mg;Ag) alloy, and lithium fluoride-aluminum (LiF:Al).

The thickness of the electrode (the first electrode, the second electrode, or the first electrode and the second electrode) is not particularly limited and may be appropriately selected taking into consideration device efficiency. For example, the thickness of the electrode may be greater than or equal to about 5 nm, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, or less than or equal to about 100 nm.

The light emitting layer 30 disposed between the first electrode and the second electrode (e.g., the anode 10 and the cathode 50) may include a plurality of semiconductor nanoparticles (e.g., blue light emitting nanoparticles, red light emitting nanoparticles, green light emitting nanoparticles, or a combination thereof). In an embodiment, the semiconductor nanoparticles may not comprise cadmium. The light emitting layer may include one or more (e.g., 2 or more or 3 or more and 10 or less) monolayers of a plurality of nanoparticles.

The light emitting layer may be patterned. In an embodiment, the patterned light emitting layer may include a blue light emitting layer disposed in the blue pixel. In an embodiment, the light emitting layer may further include a red light emitting layer disposed in the red pixel or a green light emitting layer disposed in the green pixel. In an embodiment, the light emitting layer may include a red light emitting layer disposed in the red pixel and a green light emitting layer disposed in the green pixel. Each of the (e.g., red, green, or blue) light emitting layers may be (e.g., optically) separated from an adjacent light emitting layer by a partition wall. In an embodiment, partition walls such as black matrices may be disposed between the red light emitting layer, the green light emitting layer, and the blue light emitting layer. The red light emitting layer, the green light emitting layer, and the blue light emitting layer may be optically isolated from each other.

In an embodiment, the semiconductor nanoparticle may have a core-shell structure. In an embodiment, the semiconductor nanoparticle or the core-shell structure may include a core including a first semiconductor nanocrystal and a shell including a second semiconductor nanocrystal disposed on the core and having a composition different from that of the first semiconductor nanocrystal.

The semiconductor nanoparticle (or the first semiconductor nanocrystal, the second semiconductor nanocrystal, or a combination thereof) may include a Group II-VI compound, a Group III-V compound, a Group IV-VI compound, a Group IV element or compound, a Group I-III-VI compound, a Group II-III-VI compound, a Group I-II-IV-VI compound, or a combination thereof. In an embodiment, the light emitting layer or the semiconductor nanoparticle (e.g., the first semiconductor nanocrystal or the second semiconductor nanocrystal) may not include cadmium. In an embodiment, the light emitting layer or the semiconductor nanoparticle (e.g., the first semiconductor nanocrystal or the second semiconductor nanocrystal) may not include lead. In an embodiment, the light emitting layer or the semiconductor nanoparticle (e.g., the first semiconductor nanocrystal or the second semiconductor nanocrystal) may not include a combination of lead and cadmium.

The Group II-VI compound may be a binary element compound such as ZnS, ZnSe, ZnTe, ZnO, HgS, HgSe, HgTe, MgSe, MgS, or a combination thereof; a ternary element compound such as ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or a combination thereof; a quaternary element compound such as HgZnTeS, CdZnSeS, CdZnSeTe, CdZnSTe, CdHgSeS, CdHgSeTe, CdHgSTe, HgZnSeS, HgZnSeTe, HgZnSTe, or a combination thereof; or a combination thereof. The Group II-VI compound may further include a Group III metal.

The Group III-V compound may be a binary element compound such as GaN, GaP, GaAs, GaSb, AlN, AlP, AlAs, AlSb, InN, InP, InAs, InSb, or a combination thereof; a ternary element compound such as GaNP, GaNAs, GaNSb, GaPAs, GaPSb, AlNP, AlNAs, AlNSb, AlPAs, AlPSb, InNP, InNAs, InNSb, InPAs, InPSb, or a combination thereof; a quaternary element compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof; or a combination thereof. The Group III-V compound may further include a Group II metal (e.g., InZnP).

The Group IV-VI compound may be a binary element compound such as SnS, SnSe, SnTe, PbS, PbSe, PbTe, or a combination thereof; a ternary element compound such as SnSeS, SnSeTe, SnSTe, PbSeS, PbSeTe, PbSTe, SnPbS, SnPbSe, SnPbTe, or a combination thereof; a quaternary element compound such as SnPbSSe, SnPbSeTe, SnPbSTe, or a combination thereof; or a combination thereof.

Examples of the Group I-III-VI compound may be CulnSe₂, CulnS₂, CuInGaSe, and CuInGaS, but are not limited thereto.

Examples of the Group I-II-IV-VI compound may be CuZnSnSe, and CuZnSnS, but are not limited thereto.

The Group IV element or compound may include a single-element compound such as Si, Ge, or a combination thereof; a binary element compound such as SiC, SiGe, or a combination thereof; or a combination thereof.

In an embodiment, the semiconductor nanoparticle or the first semiconductor nanocrystal may include a metal including indium, zinc, or a combination thereof and a non-metal including phosphorus, selenium, tellurium, sulfur, or a combination thereof. The first semiconductor nanocrystal may be a light emitting center.

In an embodiment, the second semiconductor nanocrystal may include a metal including indium, zinc, or a combination thereof, and a non-metal including phosphorus, selenium, tellurium, sulfur, or a combination thereof.

In an embodiment, a first semiconductor nanocrystal may include InP, InZnP, ZnSe, ZnSeS, ZnSeTe, or a combination thereof; the second semiconductor nanocrystal may include ZnSe, ZnSeS, ZnS, ZnTeSe, or a combination thereof. In an embodiment, the shell or the second semiconductor nanocrystal may include a zinc chalcogenide. The zinc chalcogenide may include zinc; and a chalcogen element (e.g., selenium, sulfur, tellurium, or a combination thereof). In an embodiment, the shell may include zinc, sulfur, and optionally further include selenium in the outermost layer.

In an embodiment, the semiconductor nanoparticle may emit blue or green light and may include a core including ZnSeTe, ZnSe, or a combination thereof and a shell including a zinc chalcogenide (e.g., ZnS, ZnSe, ZnSeS, or a combination thereof). An amount of sulfur in the shell may increase or decrease in a radial direction (from the core toward the surface), e.g., the amount of sulfur may have a concentration gradient wherein the concentration of sulfur varies radially (e.g., decreases or increases in a direction toward the core).

In an embodiment, the semiconductor nanoparticle may emit red or green light, the core may include InP, InZnP, or a combination thereof, and the shell may include a Group II metal including zinc and a non-metal including sulfur, selenium, or a combination thereof.

In an embodiment, as the semiconductor nanoparticle has a core-shell structure, on the interface between the core and the shell, an alloyed interlayer may be present or may not be present. The alloyed layer may include a homogeneous alloy or may have a concentration gradient. The gradient alloy may have a concentration gradient wherein the concentration of an element of the shell varies radially (e.g., decreases or increases in a direction toward the core).

In an embodiment, the shell may have a composition that varies in a radial direction. In an embodiment, the shell may be a multilayered shell including two or more layers. In the multilayered shell, adjacent two layers may have different compositions from each other. In the multilayered shell, a, e.g., at least one, layer may independently include a semiconductor nanocrystal having a single composition. In the multilayered shell, a, e.g., at least one, layer may independently have an alloyed semiconductor nanocrystal. In the multilayered shell, a, e.g., at least one, layer may have a concentration gradient that varies radially in terms of a composition of a semiconductor nanocrystal.

In the semiconductor nanoparticle having a core-shell structure, in an embodiment, a shell material may have a bandgap energy that is larger, e.g., greater, than that of the core. The materials of the shell may have a bandgap energy that is smaller, e.g., less, than that of the core. In the case of the multilayered shell, the bandgap energy of the outermost layer material of the shell may be greater than the bandgap energies of the core and the inner layer material of the shell (layers that are closer to the core). In the case of the multilayered shell, a semiconductor nanocrystal of each layer is selected to have an appropriate bandgap, thereby effectively showing, e.g., exhibiting, a quantum confinement effect.

The semiconductor nanoparticle according to an embodiment may include, for example, an organic ligand which is bonded or coordinated to a surface thereof. The organic ligand may help the semiconductor nanoparticle being dispersed in a solution. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH or a combination thereof. Herein, R and R′ are each independently a substituted or unsubstituted, C3 or greater, C6 or greater, or C10 or greater, and about C40 or less, C35 or less, or C25 or less, aliphatic hydrocarbon group (e.g., alkyl, alkenyl, alkynyl, etc.), a substituted or unsubstituted C6 to C40 aromatic hydrocarbon group (e.g., aryl group), or a combination thereof. The organic ligand may be used alone or as a mixture of at least two compounds.

Examples of the organic ligand may be a thiol compound such as methane thiol, ethane thiol, propane thiol, butane thiol, pentane thiol, hexane thiol, octane thiol, dodecane thiol, hexadecane thiol, octadecane thiol, benzyl thiol, and the like; an amine compound such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, trioctylamine, and the like; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, and the like; a phosphine compound such as methyl phosphine, ethyl phosphine, propyl phosphine, butyl phosphine, pentyl phosphine, octyl phosphine, dioctyl phosphine, tributyl phosphine, trioctyl phosphine, and the like; a phosphine oxide compound such as methyl phosphine oxide, ethyl phosphine oxide, propyl phosphine oxide, butyl phosphine oxide pentyl phosphine oxide, tributyl phosphine oxide, octyl phosphine oxide, dioctyl phosphine oxide, trioctyl phosphine oxide, and the like; a diphenyl phosphine or an oxide compound thereof or a triphenyl phosphine or an oxide compound thereof; a C5 to C20 alkyl phosphinic acid such as hexyl phosphinic acid, octyl phosphinic acid, dodecane phosphinic acid, tetradecane phosphinic acid, hexadecane phosphinic acid, octadecane phosphinic acid, and the like; or a C5 to C20 alkyl phosphonic acid; and the like, but are not limited thereto. Two or more different organic ligand compounds may be used.

An absorption/emission wavelength of the semiconductor nanoparticle may be controlled by adjusting the compositions, sizes, or a combination thereof of the semiconductor nanoparticle. The semiconductor nanoparticle included in the light emitting layer 3 or 30 may be configured to emit light of a desired color. The semiconductor nanoparticle may include a blue light emitting semiconductor nanoparticle, a green light emitting semiconductor nanoparticle, or a red light emitting semiconductor nanoparticle.

In an embodiment, a maximum luminescent peak wavelength of the semiconductor nanoparticle may be in a wavelength range of from ultraviolet to infrared. In an embodiment, a maximum luminescent peak wavelength of the semiconductor nanoparticle may be greater than or equal to about 300 nm, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The maximum luminescent peak wavelength of the semiconductor nanoparticle may be less than or equal to about 800 nm, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. The maximum luminescent peak wavelength of the semiconductor nanoparticle may be from about 500 nm to about 650 nm.

The semiconductor nanoparticle may emit green light (for example, on, e.g., after, an application of a voltage or irradiation with light) and a maximum luminescent peak wavelength thereof may be in the range of greater than or equal to about 500 nm (for example, greater than or equal to about 510 nm, or greater than or equal to about 515 nm) and less than or equal to about 560 nm, for example, less than or equal to about 540 nm, or less than or equal to about 530 nm. The semiconductor nanoparticle may emit red light (for example, on an application of voltage or irradiation with light), and a maximum luminescent peak wavelength thereof may be in the range of greater than or equal to about 600 nm, for example, greater than or equal to about 610 nm and less than or equal to about 650 nm, or less than or equal to about 640 nm. The semiconductor nanoparticle may emit blue light (for example, on an application of voltage or irradiation with light) and a maximum luminescent peak wavelength thereof may be greater than or equal to about 430 nm (for example, greater than or equal to about 450 nm) and less than or equal to about 480 nm (for example, less than or equal to about 465 nm).

In an embodiment, the semiconductor nanoparticle may exhibit a luminescent spectrum (e.g., photo- or electro-luminescent spectrum) with a relatively narrow full width at half maximum. In an embodiment, in the photo- or electro-luminescent spectrum, the semiconductor nanoparticle may exhibit a full width at half maximum of less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, or less than or equal to about 35 nm. The full width at half maximum may be greater than or equal to about 12 nm, greater than or equal to about 20 nm, greater than or equal to about 25 nm, or greater than or equal to about 26 nm.

The semiconductor nanoparticle may exhibit (or may be configured to exhibit) a quantum efficiency (or quantum yield) of greater than or equal to about 10%, for example, greater than or equal to about 30%, greater than or equal to about 50%, greater than or equal to about 60%, greater than or equal to about 70%, greater than or equal to about 90%, or about 100%.

The semiconductor nanoparticle may have a size (or an average size, hereinafter, can be simply referred to as “size”) of greater than or equal to about 1 nm and less than or equal to about 100 nm. The size may be a diameter or equivalent diameter converted by assuming a spherical shape from an electron microscope image when not spherical. The size may be calculated from a result of an inductively coupled plasma atomic emission spectroscopy (ICP-AES) analysis. In an embodiment, the semiconductor nanoparticle may have a size of from about 1 nm to about 50 nm, for example, from about 2 nm (or about 3 nm) to about 35 nm. In an embodiment, a size (or an average size) of the semiconductor nanoparticle may be greater than or equal to about 3 nm, greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, or greater than or equal to about 12 nm. In an embodiment, a size (or an average size) of the semiconductor nanoparticle may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, less than or equal to about 15 nm, less than or equal to about 14 nm, less than or equal to about 13 nm, or less than or equal to about 12 nm. As used herein, the average may be a mean average or a median average.

The shape of the semiconductor nanostructure or the semiconductor nanoparticle is not particularly limited. For example, the shape of the semiconductor nanoparticle may include, but is not limited to, a sphere, a polyhedron, a pyramid, a multi-pod shape, a hexahedron, a cube, a cuboid, a nanotube, a nanorod, a nanowire, a nanosheet, or a combination thereof.

The semiconductor nanoparticle may be prepared in an appropriate method. The semiconductor nanoparticle may be prepared for example by a chemical wet method wherein a nanocrystal particle may grow by a reaction between precursors in a reaction system including an organic solvent and an organic ligand. The organic ligand or the organic solvent may coordinate a surface of the semiconductor nanocrystal to control the growth thereof.

In an embodiment, for example, the method of preparing the semiconductor nanoparticle having a core/shell structure may include obtaining the core; reacting a first shell precursor including a metal (e.g., zinc) and a second shell precursor including a non-metal element (e.g., selenium, sulfur, or a combination thereof) in the presence of the core in a reaction system including an organic ligand and an organic solvent at a reaction temperature (e.g., of greater than or equal to about 180° C., greater than or equal to about 200° C., greater than or equal to about 240° C., or greater than or equal to about 280° C. and less than or equal to about 360° C., less than or equal to about 340° C., or less than or equal to about 320° C.) to form a shell including a second semiconductor nanocrystal on a core including a first semiconductor nanocrystal. The method may further include separating a core from a reaction system producing the same and dispersing the core in an organic solvent to obtain a core solution.

In an embodiment, in order to form the shell, a solvent and optionally, the first shell precursor and a ligand compound may be heated at a predetermined temperature (e.g., greater than or equal to about 100° C.) under vacuum (or vacuum-treated) and then, after introducing an inert gas into the reaction vessel, the mixture may be heat-treated again at a predetermined temperature (e.g., greater than or equal to 100° C.). Then, the core and the second shell precursor may be added to the mixture and heated at a reaction temperature. The shell precursors may be added at different ratios during a reaction time simultaneously or sequentially.

In the semiconductor nanoparticle of an embodiment, the core may be prepared in an appropriate manner. In an embodiment, the organic solvent may include a C6 to C22 primary amine such as a hexadecylamine, a C6 to C22 secondary amine such as dioctylamine, a C6 to C40 tertiary amine such as a trioctyl amine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine (e.g., trioctyl phosphine) substituted with a, e.g., at least one (e.g., 1, 2, or 3), C6 to C22 alkyl group, a phosphine oxide (e.g., trioctylphosphine oxide) substituted with a (e.g., 1, 2, or 3) C6 to C22 alkyl group, a C12 to C22 aromatic ether such as phenyl ether or benzyl ether, or a combination thereof. A combination including more than one type of organic solvent may be used,

In an embodiment, after completing the reaction (for the formation of the core or for the formation of the shell), a nonsolvent is added to reaction products and nanoparticle coordinated with the ligand compound may be separated. The nonsolvent may be a polar solvent that is miscible with the solvent used in the core formation reaction, shell formation reaction, or a combination thereof and is not capable of dispersing the prepared nanocrystals. The nonsolvent may be selected taking into consideration the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, ethylene glycol, a solvent having a similar solubility parameter to the foregoing solvents, or a combination thereof. The semiconductor nanocrystal particles may be separated through centrifugation, sedimentation, or chromatography. The separated nanocrystals may be washed with a washing solvent, if desired. The washing solvent has no particular limit and may have a similar solubility parameter to that of the ligand and may, for example, include hexane, heptane, octane, chloroform, toluene, benzene, and the like.

The semiconductor nanoparticles of an embodiment may be non-dispersible or water-insoluble in water, the aforementioned nonsolvent, or a combination thereof. The semiconductor nanoparticles of an embodiment may be dispersed in the aforementioned organic solvent. In an embodiment, the aforementioned semiconductor nanoparticles may be dispersed in a substituted or unsubstituted C6 to C40 aliphatic hydrocarbon, a substituted or unsubstituted C6 to C40 aromatic hydrocarbon, or a combination thereof.

In the electroluminescent device, a thickness of the light emitting layer may be appropriately selected. In an embodiment, the light emitting layer may include a monolayer of nanoparticles. In another embodiment, the light emitting layer may include one or more, for example, two or more, three or more, or four or more and 20 or less, 10 or less, 9 or less, 8 or less, 7 or less, or 6 or less monolayers of nanoparticles. The light emitting layer may have a thickness of greater than or equal to about 5 nm, for example, greater than or equal to about 10 nm, greater than or equal to about 20 nm, or greater than or equal to about 30 nm and less than or equal to about 200 nm, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The light emitting layer may have a thickness of, for example about 10 nm to about 150 nm, for example, about 20 nm to about 100 nm, or about 30 nm to about 50 nm.

The forming of the light emitting layer may be performed by obtaining a composition including nanoparticles (configured to emit desired light) and applying the composition on a substrate or charge auxiliary layer in an appropriate manner (e.g., by spin coating, inkjet printing, etc.) or by depositing.

A formed layer of the semiconductor nanoparticles may be contacted with an organic solution of a metal halide (e.g., an alcohol solution of zinc chloride).

The forming of the light emitting layer 3 may be performed by dispersing the semiconductor nanoparticles in a solvent (e.g., organic solvent) to obtain a composition including the semiconductor nanoparticles (e.g., a semiconductor nanoparticle dispersion) and applying or depositing the same on a substrate or a charge auxiliary layer in an appropriate manner (e.g., spin coating, inkjet printing, etc.). The forming of the light emitting layer may further include heat-treating the applied or deposited semiconductor nanoparticle layer. The heat-treating temperature is not particularly limited, and may be appropriately selected taking into consideration a boiling point of the organic solvent. For example, the heat-treating temperature may be greater than or equal to about 60° C. The organic solvent of the semiconductor nanoparticle dispersion is not particularly limited and thus may be appropriately selected. In an embodiment, the organic solvent may include a (substituted or unsubstituted) aliphatic hydrocarbon organic solvent, a (substituted or unsubstituted) aromatic hydrocarbon organic solvent, an acetate solvent, or a combination thereof.

In an embodiment, the light emitting layer may be a single layer or a multi-layered structure having at least two layers. In the multi-layered structure, adjacent layers (e.g., a first light emitting layer and a second light emitting layer) may be configured to emit a first light (e.g., green light, blue light, or red light). In the multi-layered structure, adjacent layers (e.g., a first light emitting layer and a second light emitting layer) may have the same or different composition, ligands, or a combination thereof. In an embodiment, the (multi-layered) light emitting layer may exhibit a halogen content that varies (increase or decrease) in a thickness direction. In an embodiment, in the (multi-layered) light emitting layer, the amount of the halogen may increase in a direction toward the electron auxiliary layer (e.g., the electron transport layer). In the (multi-layered) light emitting layer, the content of the organic ligand may decrease in a direction toward the electron auxiliary layer. In the (multi-layered) light emitting layer, the content of the organic ligand may increase in a direction toward the electron auxiliary layer.

In an embodiment, the light emitting layer may include a first light emitting layer including a first semiconductor nanoparticle and a second light emitting layer including a second semiconductor nanoparticle and disposed on the first light emitting layer, wherein the first semiconductor nanoparticle has a halogen (e.g., chlorine) exchanged surface and the second light emitting layer has an increased amount of an organic ligand. The first light emitting layer and optionally the second light emitting layer include halogen (e.g., in a form of a halide). An amount of organic substance in the first light emitting layer may be less than in the second light emitting layer. An amount of the halogen (e.g., chlorine) and an amount of the organic substance of the light emitting layer may be controlled in an appropriate manner (e.g., a post treatment to the formed layer). In an embodiment, a thin film of the semiconductor nanoparticles having an organic ligand (e.g., having a carboxylic acid group) is formed, which is then treated with an alcohol solution of a metal halide (e.g., a zinc halide such as a zinc chloride) to control an amount of the organic ligand of the semiconductor nanoparticles in the thin film. The treated thin film may have a controlled (e.g., reduced) amount of the organic ligand, showing a changed property (e.g., solubility) to an organic solvent. Thus, it may become possible to form a layer of semiconductor nanoparticles having a different amount of an organic ligand (e.g., a halogen treated semiconductor nanoparticle or a semiconductor nanoparticle with a ligand having a carboxylic acid group) on the treated thin film, subsequently.

An electron auxiliary layer (e.g., an electron transport layer) is disposed between the light emitting layer and the second electrode. The electron auxiliary layer include an electron transport layer. An electron injection layer may be disposed between the electron transport layer and the second electrode.

The electron transport layer includes a plurality of zinc oxide nanoparticles. The electron transport layer further includes alkali metal and halogen. The electron transport layer may further include or may not include a carbonate moiety.

The electron transport layer may be disposed directly on or may be adjacent to the light emitting layer. In an embodiment, the electron transport layer may contact the light emitting layer.

In an embodiment, the zinc oxide may include ZnO. In an embodiment, the zinc oxide may further include a metal other than the zinc, for example, Mg, Ca, Zr, W, Li, Ti, Y, Al, or a combination thereof. In an embodiment, the zinc oxide may include Zn₁₋ₓMₓO (wherein M is Mg, Ca, Zr, W, Li, Ti, Y, Al, or a combination thereof, 0≤x≤0.5). In the formula, x may be 0.01, greater than or equal to about 0.03, greater than or equal to about 0.05, greater than or equal to about 0.07, greater than or equal to about 0.1, greater than or equal to about 0.13, greater than or equal to about 0.15, greater than or equal to about 0.17, greater than or equal to about 0.2, greater than or equal to about 0.23, or greater than or equal to about 0.25. The x may be less than or equal to about 0.47, less than or equal to about 0.45, less than or equal to about 0.43, less than or equal to about 0.4, less than or equal to about 0.37, less than or equal to about 0.35, or less than or equal to about 0.3. In an embodiment, the zinc oxide may include ZnO, Zn₁₋ₓMₓO (wherein, M is Mg, Ca, Zr, W, Li, Ti, Y, Al, or a combination thereof, 0≤x≤0.5), or a combination thereof.

An average size of the zinc oxide nanoparticles may be greater than or equal to about 1 nm, greater than or equal to about 3 nm, greater than or equal to about 5 nm, or greater than or equal to about 7 nm. An average size of the zinc oxide nanoparticles may be less than or equal to about 10 nm, less than or equal to about 8 nm, less than or equal to about 7 nm, or less than or equal to about 6 nm.

In an embodiment, the alkali metal may include lithium, sodium, potassium, rubidium, cesium, or a combination thereof. The halogen may include chlorine, fluorine, bromine, iodine, or a combination thereof. In an embodiment, the alkali metal may include cesium, rubidium, or a combination thereof, the halogen may include chlorine. The electron transport layer may include cesium, rubidium, and chlorine.

The electron transport layer may include an alkali metal halide including the alkali metal and the halogen. The alkali metal halide may be readily ionized in the electron transport layer. Accordingly, the electron transport layer may include the alkali metal in a form of a positive ion and the halogen in a negative ion (e.g., as a halide).

In the electron transport layer of an embodiment, per one mole of the alkali metal, an amount of the halogen may be greater than or equal to about 0.1 moles, greater than or equal to about 0.15 moles, greater than or equal to about 0.2 moles, greater than or equal to about 0.25 moles, greater than or equal to about 0.3 moles, greater than or equal to about 0.35 moles, greater than or equal to about 0.4 moles, greater than or equal to about 0.45 moles, greater than or equal to about 0.5 moles, greater than or equal to about 0.55 moles, greater than or equal to about 0.6 moles, greater than or equal to about 0.65 moles, greater than or equal to about 0.7 moles, greater than or equal to about 0.75 moles, greater than or equal to about 0.8 moles, greater than or equal to about 0.85 moles, greater than or equal to about 0.9 moles, greater than or equal to about 0.95 moles, greater than or equal to about 1 mole, or greater than or equal to about 1.2 moles. In the electron transport layer of an embodiment, per one mole of the alkali metal, an amount of the halogen may be less than or equal to about 3 moles, less than or equal to about 2.9 moles, less than or equal to about 2.8 moles, less than or equal to about 2.7 moles, less than or equal to about 2.6 moles, less than or equal to about 2.5 moles, less than or equal to about 2.4 moles, less than or equal to about 2.3 moles, less than or equal to about 2.2 moles, less than or equal to about 2.1 moles, less than or equal to about 2 moles, less than or equal to about 1.9 moles, less than or equal to about 1.8 moles, less than or equal to about 1.7 moles, less than or equal to about 1.6 moles, less than or equal to about 1.5 moles, less than or equal to about 1.4 moles, less than or equal to about 1.3 moles, less than or equal to about 1.2 moles, less than or equal to about 1.1 moles, less than or equal to about 1 mole, less than or equal to about 0.9 moles, less than or equal to about 0.8 moles, less than or equal to about 0.7 moles, less than or equal to about 0.6 moles, less than or equal to about 0.5 moles, less than or equal to about 0.25 moles, or less than or equal to about 0.1 moles.

In the electron transport layer, per one mole of zinc, an amount of the halogen or the alkali metal may be greater than or equal to about 0.001 moles, greater than or equal to about 0.003 moles, greater than or equal to about 0.005 moles, greater than or equal to about 0.007 moles, greater than or equal to about 0.009 moles, greater than or equal to about 0.01 moles, greater than or equal to about 0.015 moles, greater than or equal to about 0.017 moles, greater than or equal to about 0.018 moles, greater than or equal to about 0.02 moles, greater than or equal to about 0.021 moles, or greater than or equal to about 0.025 moles.

In the electron transport layer, per one mole of zinc, an amount of the halogen or the alkali metal may be less than or equal to about 1 mole, less than or equal to about 0.7 moles, less than or equal to about 0.5 moles, less than or equal to about 0.1 moles, less than or equal to about 0.05 moles, less than or equal to about 0.03 moles, less than or equal to about 0.025 moles, less than or equal to about 0.02 moles, less than or equal to about 0.019 moles, or less than or equal to about 0.015 moles.

In an embodiment, the electron transport layer may exhibit a mole ratio of halogen to zinc (halogen:zinc) may be greater than or equal to about 0.01:1, greater than or equal to about 0.015:1, greater than or equal to about 0.017:1, greater than or equal to about 0.018:1, greater than or equal to about 0.02:1, greater than or equal to about 0.03:1, greater than or equal to about 0.04:1, greater than or equal to about 0.05:1, greater than or equal to about 0.06:1, greater than or equal to about 0.07:1, greater than or equal to about 0.08:1, greater than or equal to about 0.09:1, greater than or equal to about 0.1:1, greater than or equal to about 0.11:1, greater than or equal to about 0.12:1, greater than or equal to about 0.13:1, greater than or equal to about 0.14:1, greater than or equal to about 0.15:1, greater than or equal to about 0.16:1, greater than or equal to about 0.17:1, greater than or equal to about 0.18:1, greater than or equal to about 0.19:1, greater than or equal to about 0.2:1, greater than or equal to about 0.21:1, greater than or equal to about 0.22:1, greater than or equal to about 0.23:1, or greater than or equal to about 0.24:1.

In an embodiment, the electron transport layer may exhibit a mole ratio of halogen to zinc (halogen:zinc) may be less than or equal to about 0.9:1, less than or equal to about 0.8:1, less than or equal to about 0.7:1, less than or equal to about 0.6:1, less than or equal to about 0.5:1, less than or equal to about 0.4:1, less than or equal to about 0.3:1, less than or equal to about 0.2:1, less than or equal to about 0.1:1, less than or equal to about 0.09:1, less than or equal to about 0.08:1, less than or equal to about 0.07:1, less than or equal to about 0.06:1, 0.055:1, less than or equal to about 0.045:1, less than or equal to about 0.035:1, less than or equal to about 0.025:1, or less than or equal to about 0.02:1.

In the electron transport layer, a mole ratio of alkali metal to zinc (alkali metal:zinc) may be greater than or equal to about 0.01:1, greater than or equal to about 0.015:1, greater than or equal to about 0.018:1, greater than or equal to about 0.02:1, greater than or equal to about 0.022:1, greater than or equal to about 0.03:1, greater than or equal to about 0.04:1, greater than or equal to about 0.05:1, greater than or equal to about 0.06:1, greater than or equal to about 0.07:1, greater than or equal to about 0.08:1, greater than or equal to about 0.09:1, greater than or equal to about 0.1:1, greater than or equal to about 0.11:1, greater than or equal to about 0.12:1, greater than or equal to about 0.13:1, greater than or equal to about 0.14:1, greater than or equal to about 0.15:1, greater than or equal to about 0.16:1, greater than or equal to about 0.17:1, greater than or equal to about 0.18:1, greater than or equal to about 0.19:1, greater than or equal to about 0.2:1, greater than or equal to about 0.21:1, greater than or equal to about 0.22:1, greater than or equal to about 0.23:1, or greater than or equal to about 0.24:1.

In the electron transport layer, a mole ratio of alkali metal to zinc (alkali metal:zinc) may be less than or equal to about 0.9:1, less than or equal to about 0.8:1, less than or equal to about 0.7:1, less than or equal to about 0.6:1, less than or equal to about 0.5:1, less than or equal to about 0.4:1, less than or equal to about 0.3:1, less than or equal to about 0.2:1, less than or equal to about 0.1:1, or less than or equal to about 0.055:1.

In an embodiment, the electron transport layer (or the zinc oxide) may further include magnesium. The electron transport layer (or the zinc oxide) may include Zn₁₋ₓMgₓO (wherein x is greater than or equal to about 0 and less than or equal to about 0.5), ZnO, or a combination thereof.

In an embodiment, the electron transport layer may further include magnesium and, per one mole of magnesium, an amount of the halogen or the alkali metal may be greater than or equal to about 0.005 moles, greater than or equal to about 0.01 moles, greater than or equal to about 0.02 moles, greater than or equal to about 0.03 moles, greater than or equal to about 0.04 moles, greater than or equal to about 0.05 moles, greater than or equal to about 0.06 moles, greater than or equal to about 0.07 moles, greater than or equal to about 0.08 moles, greater than or equal to about 0.09 moles, greater than or equal to about 0.1 moles, 0.11 moles, greater than or equal to about 0.12 moles, greater than or equal to about 0.13 moles, greater than or equal to about 0.14 moles, greater than or equal to about 0.15 moles, greater than or equal to about 0.16 moles, or greater than or equal to about 0.165 moles.

In the electron transport layer, per one mole of magnesium, an amount of the halogen or the alkali metal may be 1 moles, less than or equal to about 0.8 moles, less than or equal to about 0.7 moles, less than or equal to about 0.6 moles, less than or equal to about 0.5 moles, less than or equal to about 0.4 moles, less than or equal to about 0.3 moles, less than or equal to about 0.2 moles, less than or equal to about 0.15 moles.

In the electron transport layer, a mole ratio of halogen to magnesium may be greater than or equal to about 0.05:1, greater than or equal to about 0.1:1, greater than or equal to about 0.11:1, greater than or equal to about 0.12:1, greater than or equal to about 0.13:1, greater than or equal to about 0.14:1, greater than or equal to about 0.15:1, greater than or equal to about 0.2:1, greater than or equal to about 0.25:1, greater than or equal to about 0.3:1, greater than or equal to about 0.35:1, greater than or equal to about 0.4:1, greater than or equal to about 0.45:1, greater than or equal to about 0.5:1, greater than or equal to about 0.55:1, greater than or equal to about 0.6:1, greater than or equal to about 0.65:1, greater than or equal to about 0.7:1, greater than or equal to about 0.75:1, greater than or equal to about 0.8:1, greater than or equal to about 0.85:1, greater than or equal to about 0.9:1, greater than or equal to about 0.95:1, or greater than or equal to about 1:1.

The electron transport layer may further include magnesium, and in the electron transport layer, a mole ratio of halogen to magnesium may be less than or equal to about 2:1, less than or equal to about 1.9:1, less than or equal to about 1.8:1, less than or equal to about 1.7:1, less than or equal to about 1.6:1, less than or equal to about 1.5:1, less than or equal to about 1.4:1, less than or equal to about 1.3:1, less than or equal to about 1.2:1, less than or equal to about 1.1:1, less than or equal to about 1:1, less than or equal to about 0.9:1, less than or equal to about 0.8:1, less than or equal to about 0.7:1, less than or equal to about 0.6:1, less than or equal to about 0.5:1, less than or equal to about 0.4:1, less than or equal to about 0.3:1, less than or equal to about 0.2:1, less than or equal to about 0.17:1, less than or equal to about 0.15:1, less than or equal to about 0.1:1, or less than or equal to about 0.05:1.

In the electron transport layer, a mole ratio of oxygen to zinc may be greater than or equal to about 0.75:1, greater than or equal to about 0.8:1, or greater than or equal to about 0.82:1. In the electron transport layer, a mole ratio of oxygen to zinc may be less than or equal to about 1.5:1, less than or equal to about 1:1, less than or equal to about 0.95:1, or less than or equal to about 0.9:1.

In the electron transport layer, a mole ratio of carbon to zinc may be greater than or equal to about 0.4:1, greater than or equal to about 0.5:1, or greater than or equal to about 0.6:1. In the electron transport layer, a mole ratio of carbon to zinc may be less than or equal to about 1:1, less than or equal to about 0.9:1, or less than or equal to about 0.8:1.

In the electron transport layer or the device, a mole ratio or a molar amount of a given element can be determined by a proper analysis tool, which is not really limited, but includes, for example, an X-ray photoelectron spectroscopy analysis or a transmission electron microscopy energy dispersive spectroscopy analysis for a given layer or a cross-section thereof.

Without wishing to be bound by any theory, it is believed that the alkali metal and the halogen may play a role of passivating defects present in the electron transport layer.

Unlike a charge auxiliary layer formed via a physical deposition, the nanoparticle based charge auxiliary layer may be prepared via a solution process. As the light emitting layer including the semiconductor nanoparticles may be susceptible to a process condition for a physical deposition, the charge auxiliary layer prepared by the solution process may be desired taking into consideration the process and property of the device. However, the present inventors have found that the charge auxiliary layer formed by the solution process may include a relatively increased number of defects in comparison with the physically deposited auxiliary layer, and the defects may cause a leakage current.

In the electroluminescent device of the embodiment, the electron transport layer is based on the zinc oxide nanoparticles and further includes the alkali metal and the halogen, both of which are readily ionized. The present inventors have found that, the alkali metal and the halogen (e.g., chlorine) included in the electron transport layer may increase the number of ions therein, contributing the passivation of the defects, whereby the electroluminescent device including the electron transport layer may exhibit improved electroluminescent properties (e.g., efficiency).

In an embodiment, as included in an electron only device (EOD), the electron transport layer may exhibit a relatively low level of a current (current density (mA/cm²))-voltage (J-V) hysteresis in a J-V scan experiment wherein a current density is measured as an applied voltage is changed in a predetermined range (e.g., from 0 volts to about 8 volts). Without wishing to be bound by any theory, it is believed that the J-V hysteresis may be related with the presence of the defects included in a given electron transport layer. The EOD including the electron transport layer of an embodiment may exhibit a hysteresis of less than or equal to about 60%, less than or equal to about 55%, less than or equal to about 52%, or less than or equal to about 51%, and greater than or equal to about 1%, greater than or equal to about 10%, greater than or equal to about 15%, or greater than or equal to about 20%, at a first sweep,

The J-V hysteresis may be determined by the following equation:

[(A2−A1)/A2]×100(%)

A1: a largest rectangle area in a forward scan in a given J-V graph

A2: a largest rectangle area in a backward scan in a given J-V graph

In an embodiment, a thickness of the electron transport layer may be greater than or equal to about 3 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, greater than or equal to about 20 nm, greater than or equal to about 21 nm, greater than or equal to about 22 nm, greater than or equal to about 23 nm, greater than or equal to about 24 nm, greater than or equal to about 25 nm, greater than or equal to about 26 nm, greater than or equal to about 27 nm, greater than or equal to about 28 nm, greater than or equal to about 29 nm, greater than or equal to about 30 nm, greater than or equal to about 31 nm, greater than or equal to about 32 nm, greater than or equal to about 33 nm, greater than or equal to about 34 nm, or greater than or equal to about 35 nm. In an embodiment, a thickness of the electron transport layer may be less than or equal to about 90 nm, less than or equal to about 80 nm, less than or equal to about 70 nm, less than or equal to about 60 nm, less than or equal to about 50 nm, less than or equal to about 45 nm, less than or equal to about 40 nm, or less than or equal to about 35 nm.

The electron transport layer may have a first surface facing the light emitting layer and a second surface opposite to the first surface.

As the electron transport layer is divided into two or three portions in a thickness direction thereof, a total amount of the alkali metal and the halogen in a first portion including the first surface may be greater than a total amount of the alkali metal and the halogen in a second portion including the second surface. The second portion may include or may not include the alkali metal. The second portion may include or may not include the halogen. The second portion may include or may not include the alkali metal and the halogen.

The electron transport layer may include a first layer including the first surface and a second layer including the second surface.

In an embodiment, a thickness of the first layer may be greater than or equal to about 1 nm, greater than or equal to about 2 nm, greater than or equal to about 3 nm, greater than or equal to about 4 nm, greater than or equal to about 5 nm, greater than or equal to about 6 nm, greater than or equal to about 7 nm, greater than or equal to about 8 nm, or greater than or equal to about 9 nm. In an embodiment, a thickness of the first layer may be less than or equal to about 15 nm, less than or equal to about 13 nm, less than or equal to about 11 nm, less than or equal to about 10 nm, less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, or less than or equal to about 2 nm.

In an embodiment, a thickness of the second layer may be greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, greater than or equal to about 20 nm, greater than or equal to about 25 nm, or greater than or equal to about 30 nm.

In an embodiment, a thickness of the second layer may be less than or equal to about 50 nm, less than or equal to about 45 nm, less than or equal to about 40 nm, less than or equal to about 35 nm, less than or equal to about 30 nm, less than or equal to about 25 nm, less than or equal to about 20 nm, or less than or equal to about 15 nm.

In an embodiment, a thickness of the first layer may be less than or equal to a thickness of the second layer. In an embodiment, a thickness of the first layer may be greater than or equal to a thickness of the second layer.

In an embodiment, a zinc oxide nanoparticle of the first layer may further include or may not include Mg, Ca, Zr, W, Li, Ti, Y, Al, or a combination thereof. In an embodiment, a zinc oxide nanoparticle of the second layer may further include or may not include Mg, Ca, Zr, W, Li, Ti, Y, Al, or a combination thereof.

In an embodiment, the first layer may include ZnO nanoparticles and the second layer may include ZnMgO nanoparticles. In an embodiment, the second layer may include ZnO nanoparticles and the first layer may include ZnMgO nanoparticles. In an embodiment, the first layer may include ZnMgO nanoparticles and the second layer may include ZnMgO nanoparticles.

In an embodiment, the first layer (or the first portion), the second layer (or the second portion), or a combination thereof may further include or may not include a carbonate moiety.

In an embodiment, the first layer (or the first portion), the second layer (of the second portion), or a combination thereof may further include an alkali metal. The alkali metal may include an, e.g., at least one (e.g., at least two), alkali metal. In an embodiment, the first layer, the second layer, or a combination thereof may include cesium, rubidium, or a combination thereof.

In an embodiment, the first portion or the first layer may be disposed between the light emitting layer and the second portion (or the second layer). Without wishing to be bound by any theory, it is believed that the first portion or the first layer may control (or suppress) a flow of holes depending on an applied voltage. The present inventors have found that the first portion or the first layer may block a hole at a relatively low voltage, for example, of less than or equal to about 4 volts, less than or equal to about 3 volts, or less than or equal to about 2 volts, whereby the electroluminescent device may exhibit an increased efficiency, while controlling a maximum amount of cumulated holes between the light emitting layer and the electron transport layer at a relatively high voltage, for example, of greater than about 4 volts, for example, greater than or equal to about 5 volts, greater than or equal to about 6 volts, greater than or equal to about 7 volts, or greater than or equal to about 8 volts, and less than or equal to 10 volts), whereby contributing the prevention of the interface deterioration in the device.

Without wishing to be bound by any theory, it is believed that such a hole control, e.g., control of a flow of holes or a maximum amount of cumulated holes between the light emitting layer and the electron transport layer, of the electron transport layer of an embodiment may further contribute to an increased lifespan of the electroluminescent device of an embodiment. In an electroluminescent device, the electron transport layer may be configured to increase a conductivity of a majority carrier and to block a minority carrier, but the present inventors have found that such an approach may affect the electroluminescent properties of a given device, but at the same time, the minority carrier blocking may cause minority carrier accumulation at the light emitting layer and the electron transport layer, which may lead to the interface deterioration during the operation of the device. Without wishing to be bound by any theory, it is also believed that the minority carrier accumulation or the interface deterioration may put the given device under an energy band bending and may result in a non-radiative recombination at the interface or generate a leakage path for the device. Accordingly, the lifespan of the device may be adversely affected.

In an embodiment, the electroluminescent device includes the electron transport layer described herein (e.g., having the first layer or the first portion and the second layer or the second portion), which may control a limitation about accepting the accumulated minority carrier and exhibit an improved electron transport ability. Without wishing to be bound by any theory, it is believed that the first layer or the first portion may act as a hole block controlling layer (HBCL) at a limited thickness, allowing the entire electron transport layer to maintain an improved level of an electron transport ability (ET). In addition, the HBCL layer may contribute to achieving a high efficiency at a relatively low voltage (e.g., that does not cause substantial damage to a device), and may allow at least a portion of holes accumulated at an interface to flow at a relatively high voltage (e.g., that may raise a concern about the device damage), substantially addressing the interface deterioration problem between the light emitting layer and the electron transport layer.

Accordingly, in a graph of external quantum efficiency versus luminance, e.g., an external quantum efficiency versus a luminance curve, the electroluminescent device may exhibit a ratio of an external quantum efficiency to a maximum external quantum efficiency that is less than or equal to about 0.7:1, e.g., less than or equal to about two thirds (⅔) or less than or equal to about one half (½), and greater than or equal to about 0.1:1, greater than or equal to about 0.3:1, greater than or equal to about 0.5:1, greater than or equal to about 0.6:1, or greater than or equal to about 0.65:1, at a point having a luminance half a maximum luminance.

As, e.g., when, operated at a predetermined luminance (e.g., about 650 nit), the electroluminescent device of an embodiment may T90 of greater than or equal to about 10 hours, greater than or equal to about 20 hours, greater than or equal to about 30 hours, greater than or equal to about 40 hours, greater than or equal to about 50 hours, greater than or equal to about 60 hours, greater than or equal to about 70 hours, greater than or equal to about 80 hours, greater than or equal to about 90 hours, greater than or equal to about 100 hours, greater than or equal to about 110 hours, greater than or equal to about 120 hours, greater than or equal to about 130 hours, greater than or equal to about 140 hours, greater than or equal to about 150 hours, greater than or equal to about 160 hours, greater than or equal to about 170 hours, greater than or equal to about 180 hours, greater than or equal to about 190 hours, or greater than or equal to about 200 hours. In an embodiment, the electroluminescent device may exhibit a T90 of from about 10 hours to about 10,000 hours, from about 50 hours to about 5,000 hours, from about 100 hours to about 1,000 hours, from about 200 hours to about 800 hours, or a combination thereof, as operated at a predetermined luminance (e.g., about 650 nit).

As operated at a predetermined luminance (e.g., about 650 nit) the electroluminescent device of an embodiment may have, e.g., exhibit, a T50 of greater than or equal to about 400 hours, greater than or equal to about 450 hours, greater than or equal to about 500 hours, greater than or equal to about 600 hours, or greater than or equal to about 700 hours. The T50 may be from about 100 hours to about 10,000 hours, from about 500 hours to about 5,000 hours, from about 1,000 hours to about 2,500 hours, from about 1,500 hours to about 1,800 hours, or a combination thereof. The T50 may be greater than or equal to about 500 hours, or greater than or equal to about 650 hours, and less than or equal to about 2,000 hours, or less than or equal to about 1,000 hours.

The electron transport layer may be formed by a solution process, showing a relatively high level of surface roughness. The electron transport layer may have a first surface facing the light emitting layer and a second surface facing the first surface, and in the cross-section analysis of the device, a (inter)surface roughness of the second surface of the electron transport layer may be greater than or equal to about 3 nm, greater than or equal to about 5 nm, greater than or equal to about 7 nm, greater than or equal to about 10 nm, or greater than or equal to about 12 nm and less than or equal to about 100 nm, or less than or equal to about 50 nm.

In an embodiment, as determined in an atomic force microscopy analysis, a surface roughness (RMS) of the second surface of the electron transport layer may be greater than or equal to about 0.1 nm, greater than or equal to about 0.3 nm, greater than or equal to about 0.5 nm, greater than or equal to about 0.6 nm and less than or equal to about 5 nm, less than or equal to about 4 nm, less than or equal to about 3 nm, less than or equal to about 2 nm, or less than or equal to about 1 nm.

In an embodiment, the electron transport layer may be prepared in a solution process. In an embodiment, the electron transport layer may be prepared by dispersing a plurality of zinc oxide nanoparticles and an alkali metal halide in an organic solvent (for example, a polar solvent, a non-polar solvent, or a combination thereof) to obtain an electron transport layer precursor dispersion, which is then applied to form a film. The electron transport layer precursor dispersion may be applied to the light emitting layer. The solution process may further include removing the organic solvent from the formed film for example by evaporation. The process may further include dispersing a plurality of zinc oxide nanoparticles in an organic solvent to obtain an additional dispersion, applying the additional dispersion on the formed film, and optionally removing the organic solvent.

In an embodiment, the organic solvent may dissolve the alkali metal halide. The organic solvent may not have a substantial effect on the light emitting layer. The organic solvent may include a C1 to C10 alcohol solvent, or a combination thereof.

The electron transport precursor dispersion, the additional dispersion, or a combination thereof may further include an additional alkali metal compound. The additional alkali metal compound may include an alkali metal that is different from the alkali metal of the alkali metal halide. In an embodiment, the alkali metal halide may include cesium and the additional alkali metal compound may include rubidium. The additional alkali metal compound may include or may not include a carbonate moiety. In an embodiment, the additional alkali metal compound may include or may not include a halide moiety.

The alkali metal halide may be commercially available or prepared in any suitable method. The alkali metal halide may include lithium fluoride, sodium fluoride, potassium fluoride, cesium fluoride, rubidium fluoride, lithium chloride, sodium chloride, potassium chloride, cesium chloride, rubidium chloride, lithium bromide, sodium bromide, potassium bromide, cesium bromide, rubidium bromide, lithium iodide, sodium iodide, potassium iodide, cesium iodide, rubidium iodide, or a combination thereof.

The zinc oxide nanoparticle may be prepared in any suitable method, which is not particularly limited. In an embodiment, the zinc oxide (e.g., zinc magnesium oxide) nanoparticle may be prepared by placing a zinc compound (e.g., an organic zinc compound such as zinc acetate dihydrate) and an additional metal compound (e.g., an organic additional metal compound such as magnesium acetate tetrahydrate) in an organic solvent in a flask to have a desired mole ratio and heating the same at a predetermined temperature (e.g., from about 40° C. to about 120° C., or from about 60° C. to about 100° C.) (e.g., under atmosphere), and adding a precipitation accelerating solution (for example, an ethanol solution of tetramethyl ammonium hydroxide pentahydrate) at a predetermined rate with stirring. The prepared zinc oxide nanoparticle (e.g., ZnₓMg₁₋ₓO nanoparticle) may be recovered from a resulting solution for example via centrifugation.

In an embodiment, the electron auxiliary layer 4 may further include an electron injection layer. In an embodiment, a thickness of the electron auxiliary layer or the electron auxiliary layer may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm.

In an embodiment, the electroluminescent device may further include a hole auxiliary layer 2, 20 between the first electrode 1 and the light emitting layer 3. The hole auxiliary layer 2, 20 may include a hole injection layer, a hole transport layer, an electron blocking layer, or a combination thereof. The hole auxiliary layer 2, 20 may be a layer of a single component or a multilayer structure in which adjacent layers include different components.

The HOMO energy level of the hole auxiliary layer 2 may have a HOMO energy level that can be matched with the HOMO energy level of the light emitting layer 3 in order to enhance mobility of holes transferred from the hole auxiliary layer 2 to the light emitting layer 3. In an embodiment, the hole auxiliary layer 2 may include a hole injection layer close to the first electrode 1 and a hole transport layer close to the light emitting layer 3.

The material included in the hole auxiliary layer 2 (e.g., a hole transport layer, a hole injection layer, or an electron blocking layer) is not particularly limited, and may include, for example, poly(9,9-dioctyl-fluorene-co-N-(4)-butylphenyl)-diphenylamine) (TFB), polyarylamine, poly(N-vinylcarbazole), poly(3,4-ethylenedioxythiophene (PEDOT), poly(3,4-ethylenedioxythiophene) polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl (α-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-toylamino)phenylcyclohexane (TAPC), a p-type metal oxide (e.g., NiO, WO₃, MoO₃, etc.), a carbon-based material such as graphene oxide, or a combination thereof, but is not limited thereto.

In the hole auxiliary layer, the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 35 nm, or less than or equal to about 30 nm, but is not limited thereto.

A device according to an embodiment as shown in FIG. 2, the device may have a normal structure. In an embodiment, in the device, the anode 10 disposed on the transparent substrate 100 may include a metal oxide-based transparent electrode (e.g., an ITO electrode), and the cathode 50 facing the anode 10 may include a conductive metal (e.g., having a relatively low work function, Mg, Al, etc.). The hole auxiliary layer 20 (e.g., a hole injection layer such as PEDOT:PSS, a p-type metal oxide, or a combination thereof; a hole transport layer such as TFB, polyvinylcarbazole (PVK), or a combination thereof; or a combination thereof) may be provided between the transparent electrode 10 and the light emitting layer 30. The hole injection layer may be disposed close to the transparent electrode and the hole transport layer may be disposed close to the light emitting layer. The electron auxiliary layer 40 such as an electron injection/transport layer may be disposed between the light emitting layer 30 and the cathode 50.

A device according to another embodiment may have an inverted structure as depicted in FIG. 3. Herein, the cathode 50 disposed on the transparent substrate 100 may include a metal oxide-based transparent electrode (e.g., ITO), and the anode 10 facing the cathode may include a metal (e.g., having a relatively high work function, Au, Ag, etc.). For example, an (optionally doped) n-type metal oxide (crystalline Zn metal oxide) or the like may be disposed as an electron auxiliary layer 40 (e.g., an electron transport layer) between the transparent electrode 50 and the light emitting layer 30. MoO₃ or other p-type metal oxide may be disposed as a hole auxiliary layer 20 (e.g., a hole transport layer including TFB, PVK, or a combination thereof; a hole injection layer including MoO₃ or other p-type metal oxide; or a combination thereof) between the metal anode 10 and the light emitting layer 30.

The aforementioned device may be manufactured by an appropriate method. For example, the electroluminescent device may be manufactured by optionally forming a hole auxiliary layer (e.g., by deposition or coating) on a substrate on which an electrode is disposed, forming a light emitting layer including semiconductor nanoparticle (e.g., a pattern of the aforementioned semiconductor nanoparticle), and forming an electron auxiliary layer on the light emitting layer, and then forming an electrode (e.g., by vapor deposition or coating) on the electron transport layer. A method of forming the electrode/hole auxiliary layer/electron auxiliary layer such as an electron injection layer may be appropriately selected and is not particularly limited. The formation of the light emitting layer and the electron transport layer are the same as described herein.

The electroluminescent device of an embodiment may exhibit improved electroluminescent properties together with a longer lifespan. In an embodiment, the electroluminescent device may have a maximum external quantum efficiency (EQE) of greater than or equal to about 5%, greater than or equal to about 5.5%, greater than or equal to about 6%, greater than or equal to about 6.5%, greater than or equal to about 7%, greater than or equal to about 7.5%, greater than or equal to about 7.7%, greater than or equal to about 8%, greater than or equal to about 8.5%, greater than or equal to about 9%, greater than or equal to about 9.5%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. The maximum external quantum efficiency (EQE) may be less than or equal to about 50%, less than or equal to about 40%, less than or equal to about 30%, or less than or equal to about 20%.

The electroluminescent device of an embodiment may show a maximum luminance of greater than or equal to about 60,000 cd/m², greater than or equal to about 80,000 cd/m², greater than or equal to about 90,000 cd/m², greater than or equal to about 100,000 cd/m², greater than or equal to about 120,000 cd/m², greater than or equal to about 200,000 cd/m², greater than or equal to about 300,000 cd/m², greater than or equal to about 310,000 cd/m², greater than or equal to about 320,000 cd/m², greater than or equal to about 330,000 cd/m², greater than or equal to about 340,000 cd/m², greater than or equal to about 350,000 cd/m², greater than or equal to about 360,000 cd/m², greater than or equal to about 370,000 cd/m², greater than or equal to about 380,000 cd/m², greater than or equal to about 390,000 cd/m², greater than or equal to about 400,000 cd/m², greater than or equal to about 440,000 cd/m², greater than or equal to about 500,000 cd/m², greater than or equal to about 550,000 cd/m², or greater than or equal to about 600,000 cd/m². The maximum luminance may be less than or equal to about 700,000 cd/m², less than or equal to about 600,000 cd/m², or less than or equal to about 500,000 cd/m².

In an embodiment, a display device including the electroluminescent device described herein.

The display device may include a first pixel and a second pixel that is configured to emit light different from the first pixel. The first pixel, the second pixel, or a combination thereof may include the electroluminescent device of an embodiment. The display device may include a blue pixel, a red pixel, a green pixel, or a combination thereof. In the display device, the red pixel may include a red light emitting layer including a plurality of red light emitting semiconductor nanoparticles, the green pixel may include a green light emitting layer including a plurality of green light emitting semiconductor nanoparticles, and the blue pixel may include a blue light emitting layer including a plurality of blue light emitting semiconductor nanoparticles,

The display device or an electronic apparatus may include (or may be) a television, a virtual reality/augmented reality (VR/AR), a handheld terminal, a monitor, a notebook computer, an electronic display board, a camera, or a part for an automatic, e.g., autonomous, vehicle.

Specific examples are described below. However, the examples described below are only for specifically illustrating or explaining the disclosure, and the scope of the disclosure is not limited thereto.

### EXAMPLES

### 1. Electroluminescence Measurement

A current according to an applied voltage is measured with a Keithley 2635B source meter, and a CS2000 spectrometer is used to measure electroluminescent properties (e.g., luminance) of a light-emitting device.

### 2. Life-Span Characteristics

T90: When a device is driven (operated) at a predetermined brightness (e.g., 650 nit), the time (hours (hr)) for the brightness to decrease to 90% of the initial brightness (100%).
T50: When a device is driven (operated) at a predetermined brightness (e.g., 650 nit), the time (hr) for the brightness to decrease to 50% of the initial brightness (100%).

### 3. X-Ray Photoelectron Spectroscopy (XPS) Analysis

An X-ray photoelectron spectroscopy analysis is conducted for using Quantum2000 manufactured by Physical Electronics.

### 4. Atomic Force Microscopy (AFM) Analysis

An AFM analysis is conducted by using Bruker PeakForce TUNA Application Module for Icon SPM.

### 5. TEM Analysis

Transmission electron microscopy analysis is conducted using an UT F30 Tecnai electron microscope.

### 6. Photoluminescence Analysis

Photoluminescence (PL) spectroscopy analysis is conducted using a Hitachi F-7000 spectrophotometer.

The following synthesis is performed under an inert gas atmosphere (e.g., under nitrogen) unless otherwise specified. A precursor content is provided as a molar content, unless otherwise specified.

### Synthesis Example 1

Indium acetate, zinc acetate, and palmitic acid are dissolved in 1-octadecene in a 200 milliliter (mL) reaction flask and heated at 120° C. under vacuum. After 1 hour, a nitrogen atmosphere is added to the reaction flask and the temperature of the reaction flask is increased to 280° C. A mixed solution of tris(trimethylsilyl)phosphine ((TMS)₃P) and trioctyl phosphine is rapidly injected into the reaction flask, and the reaction is allowed to continue for a predetermined time to obtain a desired first absorption wavelength in an ultraviolet-visible (UV-Vis) absorption spectrum. The reaction solution is rapidly cooled to room temperature. Acetone is added to facilitate formation of a precipitate, the precipitate is separated with a centrifuge, and the isolated precipitate (cores) is dispersed in toluene to prepare a toluene dispersion.

(TMS)₃P is used in an amount of 0.5 moles per one mole of indium. The cores have a size of about 2 nanometers (nm).

Selenium is dispersed in trioctyl phosphine (TOP) to prepare a Se/TOP stock solution, and sulfur is dispersed in trioctyl phosphine to prepare a S/TOP stock solution.

Zinc acetate and oleic acid are dissolved in trioctylamine in a 200 mL reaction flask, and the reaction mixture is vacuum-treated at 120° C. for 10 minutes. The reaction flask is filled with nitrogen (N₂), the solution is heated to 320° C., and the toluene dispersion of the prepared semiconductor nanocrystal is added to the reaction flask. Thereafter, the Se/TOP stock solution, and optionally zinc acetate are injected into the reaction flask three times. A reaction is carried out to obtain a particle having a ZnSe shell formed on the core.

Then, the S/TOP stock solution, and optionally zinc acetate are injected into the reaction flask. A reaction is carried out to obtain a particle having a ZnS shell formed on the ZnSe shell.

An excess amount of ethanol is added to facilitate formation of the light emitting nanostructures, which are then separated with a centrifuge. After the centrifugation, the supernatant is discarded and the precipitate is dried and then dispersed in toluene or chloroform. For the obtained semiconductor nanoparticles, a photoluminescent analysis is carried out, and the results confirms that the obtained semiconductor nanoparticles emit green light.

### Synthesis Example 2: Synthesis of ZnMgO (ZMO) Nanoparticles

Zinc acetate dihydrate and magnesium acetate tetrahydrate are added into a reactor including dimethylsulfoxide to provide a mole ratio shown in the following chemical formula and heated at 60° C. in an air atmosphere. Subsequently, an ethanol solution of tetramethylammonium hydroxide pentahydrate is added into the reactor in a dropwise fashion at a speed of 3 milliliters per minute (mL/min). After stirring the mixture, the obtained Zn₁₋ₓMgₓO nanoparticles are centrifuged and dispersed in ethanol to provide an ethanol dispersion of Zn₁₋ₓMgₓO (x=0.15) nanoparticles.

The obtained nanoparticles are analyzed by a transmission electron microscopic analysis, and the results show that the particles have an average particle size of about 3 nm.

### Synthesis Example 3: Synthesis of ZnO Nanoparticles

ZnO nanoparticles are prepared in accordance with the same procedure as in Reference Example 2, except that the magnesium acetate tetrahydrate is not used in the preparation. The obtained ZnO nanoparticles are analyzed with transmission electron microscopy, and the results show that the particles have an average particle size of about 3.7 nm.

### Experimental Example 1: Electron Only Device (EOD) Analysis

Semiconductor nanoparticles prepared in Synthesis Example 1 are dispersed in octane to provide a semiconductor nanoparticle solution.

Zinc magnesium oxide nanoparticles prepared in Synthesis Example 2 are dispersed in ethanol to prepare a first dispersion for an electron transport layer (ETL).

Zinc magnesium oxide nanoparticles prepared in Synthesis Example 2 and cesium chloride (CAS: 7647-17-8) are dispersed in ethanol at a concentration of Table 1 to prepare a second dispersion for an ETL.

Electron Only Device (EOD) is Prepared as Follows:

On a glass substrate deposited with an indium tin oxide (ITO) electrode (anode), the first dispersion or the second dispersion are spin-coated and heat treated at 80° C. for 30 minutes to form an electron transport layer having a thickness of about 30 nm. On the electron transport layer thus prepared, the semiconductor nanoparticle solution is spin-coated to form a light emitting layer. On the light emitting layer, the first dispersion or the second dispersion is used to form an electron transport layer having a thickness of about 30 nm, respectively, and then, an AI electrode is deposited thereon.

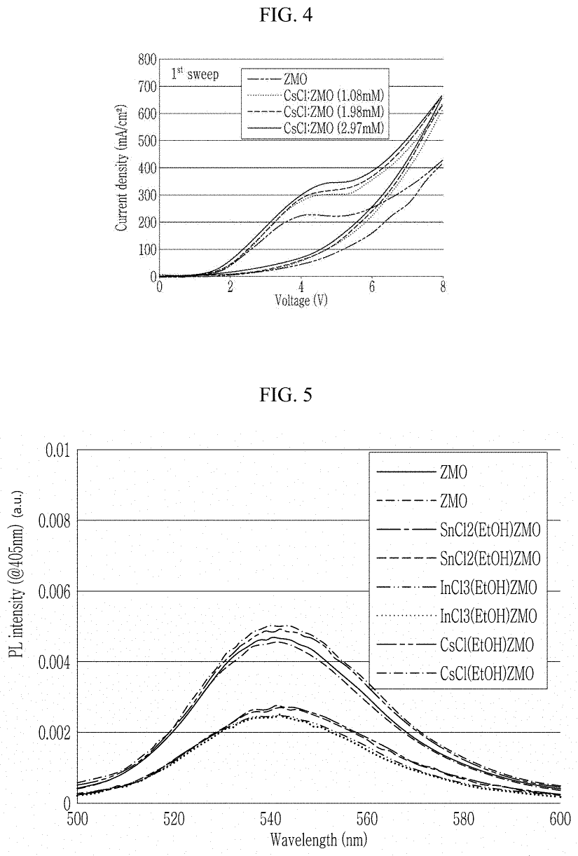

A voltage (0 to 8 volts (V), i.e., a bias voltage) is applied between the ITO electrode and the AI electrode, in a forward scan or in a backward scan and a current density is measured. The results are shown in Table 1, and FIG. 4.

TABLE 1

| Cesium halide | | Maximum | |
|---|---|---|---|
| concentration in | Maximum Current | Current | |
| the dispersion | Density during the 1^{st} | Density | |
| (millimolar | sweep (milliamperes | during the 3^{rd} | Hysteresis |
| (millimoles per | per square centimeter | sweep | during |
| liter (mM))) | (mA/cm²)) | (mA/cm²) | 1^{st} sweep |
| 0 | 420 | 330 | 62% |
| 1.08 | 610 | 422 | 52.4% |
| 1.98 | 630 | 453 | 49.2% |
| 2.97 | 670 | 467 | 46.6% |

Table 1 and FIG. 4 confirm that the electron transport layer including the Cs chloride shows an increased current density or an increased electron transport ability (for example, as a blending concentration increases), and a decreased level of hysteresis. Without wishing to be bound by any theory, it is believed that the results indicate that the blending of the cesium chloride results in a passivation on a defect site in the electron transport layer.

### Experimental Example 2

Zinc magnesium oxide nanoparticles prepared in Synthesis Example 2 are dispersed in ethanol to prepare a first dispersion for an ETL.

Zinc magnesium oxide nanoparticles prepared in Synthesis Example 2 and cesium chloride (CAS: 7647-17-8, concentration: 8.91 mM) are dispersed in ethanol to prepare a second dispersion for an ETL.

Zinc magnesium oxide nanoparticles prepared in Synthesis Example 2 and tin chloride (SnCl₂, Cas no: 10025-69-1, concentration: 8.91 mM) are dispersed in ethanol to prepare a third dispersion for an ETL.

Zinc magnesium oxide nanoparticles prepared in Synthesis Example 2 and indium chloride (InCl₃, CAS Number: 10025-82-8, concentration: 8.91 mM) are dispersed in ethanol to prepare a fourth dispersion for an ETL.

Using the first dispersion to the fourth dispersion respectively, an electroluminescent device having a structure of ITO/poly(3,4-ethylenedioxythiophene (PEDOT) (35 nm)/poly(9,9-dioctyl-fluorene-co-N-(4)-butylphenyl)-diphenylamine) (TFB) (30 nm)/quantum dot (QD) emitting layer (EML) (40 nm)/ETL (30 nm)/A1 (100 nm) is prepared as follows:

A glass substrate deposited with indium tin oxide (ITO) is surface treated with UV-ozone for 15 minutes, and then spin-coated with a poly(3,4-ethylenedioxythiophene) polystyrene sulfonate (PEDOT:PSS) solution (H.C. Starks) and heated at 150° C. for 10 minutes under air atmosphere and heated again at 150° C. for 20 to 30 minutes under N₂ atmosphere to provide a hole injection layer (HIL) having a thickness of 35 nm.

Subsequently, poly[(9,9-dioctylfluorenyl-2,7-diyl-co(4,4′-(N-4-butylphenyl)diphenylamine] solution (TFB) (Sumitomo) is spin-coated on the hole injection layer and heated at 150° C. for 30 minutes to provide a hole transport layer (HTL) having a thickness of 30 nm.

The semiconductor nanoparticle dispersion obtained from Synthesis Example 1 is spin-coated on the hole transport layer to obtain a light emitting layer having a thickness of 40 nm (20 nm+20 nm).

Each of the first to fourth dispersions is spin-coated on the light emitting layer and a heat treatment at 80° C. for 30 minutes is performed to provide an electron transport layer having a thickness of 30 nm.

Aluminum (Al) is vacuum-deposited on the obtained electron transport layer to prepare a second electrode of a thickness of about 100 nm, providing an electroluminescent device.

For the device prepared using the first dispersion, an XPS analysis is conducted and mole ratios of magnesium, chlorine, and cesium to zinc are summarized in Table 2.

TABLE 2

| | Mg:Zn | Cl:Zn | Cs:Zn |
|---|---|---|---|
| CsCl:ZMO (the first dispersion) | 0.13:1 | 0.018369:1 | 0.022105:1 |

For each of the prepared devices, a photoluminescent spectroscopy analysis is conducted and the results are shown in FIG. 5. From the results of FIG. 5 confirm that the electron transport layer including the cesium chloride results in an improvement of a photoluminescent property of the device, while the zinc oxide based electron transport layer including indium chloride and tin chloride cause deterioration of the PL property of the device.

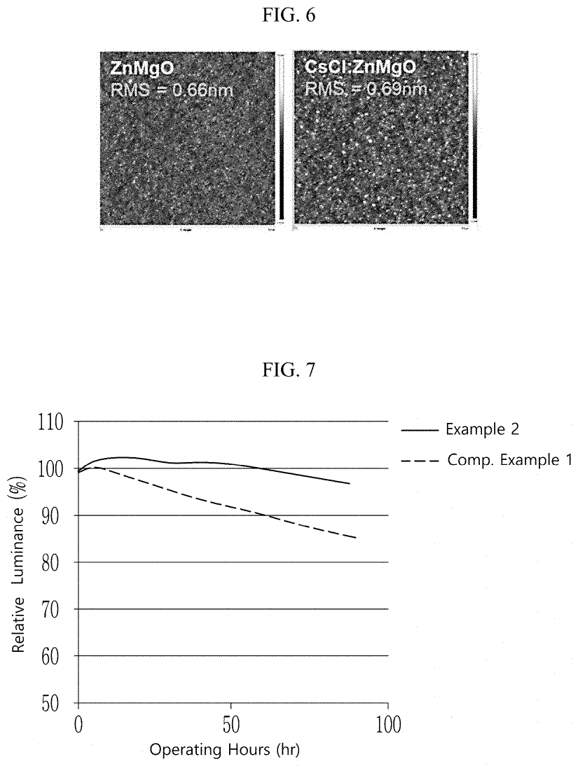

For the electron transport layer obtained by using the first dispersion and the electron transport layer obtained by using the second dispersion, an AFM analysis is conducted and the results are shown in FIG. 6. The results of FIG. 6 confirm that the addition of the cesium chloride does not substantially affect the surface roughness of the electron transport layer.

### Example 1: CsCl:ZMO Single Layer Electron Transport Layer

An ETL dispersion including the zinc magnesium oxide prepared in Synthesis Example 2 and cesium chloride (concentration: 8.91 mM) in ethanol is prepared.

An electroluminescent device is prepared in the same manner as Experimental Example 2 except for using the ETL dispersion thus obtained. For the prepared device, electroluminescent properties are measured and the results are shown in Table 3.

### Example 2: CsCl:Rb:ZMO/ZnO Double Layer Electron Transport Layer

A first ETL dispersion including the zinc magnesium oxide prepared in Synthesis Example 2; and cesium chloride and a rubidium salt compound (a total concentration: 8.91 mM) in ethanol is prepared.

A second ETL dispersion including the zinc oxide prepared in Synthesis Example 3 in ethanol is prepared.

An electroluminescent device is prepared in the same manner as Experimental Example 2 except that the electron transport layer is prepared in the following manner:

On the light emitting layer, the first ETL dispersion is spin-coated and heat-treated for 30 minutes to obtain a first electron transport layer (thickness: 5 nm). Then, on the first electron transport layer, the second ETL dispersion is spin-coated and heat-treated for 30 minutes to obtain a second electron transport layer (thickness: 25 nm).

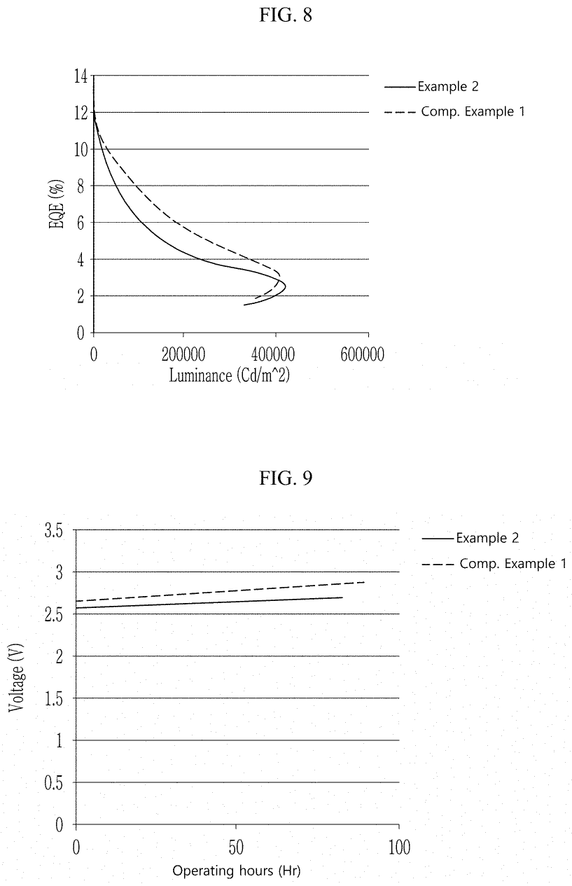

For the prepared device, electroluminescent properties are measured and the results are shown in Table 3, FIG. 7, FIG. 8, and FIG. 9.

### Example 3: CsCl:ZMO/ZMO Double Layer Electron Transport Layer

A first ETL dispersion including the zinc magnesium oxide prepared in Synthesis Example 2 and cesium chloride (concentration: 8.91 mM) in ethanol is prepared.

A second ETL dispersion including the zinc magnesium oxide prepared in Synthesis Example 2 in ethanol is prepared.

An electroluminescent device is prepared in the same manner as Experimental Example 2 except that the electron transport layer is prepared in the following manner:

On the light emitting layer, the first ETL dispersion is spin-coated and heat-treated for 30 minutes to obtain a first electron transport layer (thickness: 5 nm). Then, on the first electron transport layer, the second ETL dispersion is spin-coated and heat-treated for 30 minutes to obtain a second electron transport layer (thickness: 25 nm).

For the prepared device, electroluminescent properties are measured and the results are shown in Table 3.

### Example 4: CsCl:Rb:ZMO Single Layer Electron Transport Layer

An ETL dispersion including the zinc magnesium oxide prepared in Synthesis Example 2 and cesium chloride and a rubidium salt compound (a total concentration: 8.91 mM) in ethanol is prepared.

An electroluminescent device is prepared in the same manner as Experimental Example 2 except that the electron transport layer is prepared in the following manner:

On the light emitting layer, the prepared ETL dispersion is spin-coated and heat-treated for 30 minutes to obtain a first electron transport layer (thickness: 30 nm). For the prepared device, electroluminescent properties are measured and the results are shown in Table 3.

### Example 5: CsCl:ZMO/ZMO Double Layer Electron Transport Layer

A first ETL dispersion including the zinc magnesium oxide prepared in Synthesis Example 2 and cesium chloride (concentration: 8.91 mM) in ethanol is prepared.

A second ETL dispersion including the zinc magnesium oxide prepared in Synthesis Example 2 in ethanol is prepared.

An electroluminescent device is prepared in the same manner as Experimental Example 2 except that the electron transport layer is prepared in the following manner:

On the light emitting layer, the first ETL dispersion is spin-coated and heat-treated for 30 minutes to obtain a first electron transport layer (thickness: 5 nm). Then, on the first electron transport layer, the second ETL dispersion is spin-coated and heat-treated for 30 minutes to obtain a second electron transport layer (thickness: 25 nm).

For the prepared device, electroluminescent properties are measured and the results are shown in Table 3.

### Comparative Example 1

An ETL dispersion including the zinc magnesium oxide prepared in Synthesis Example 2 in ethanol is prepared.

An electroluminescent device is prepared in the same manner as Experimental Example 2 except for using the ETL dispersion thus obtained. For the prepared device, electroluminescent properties are measured and the results are shown in Table 3, FIG. 7, FIG. 8, and FIG. 9.

### Comparative Example 2

An ETL dispersion including the zinc oxide prepared in Synthesis Example 3 in ethanol is prepared.

An electroluminescent device is prepared in the same manner as Experimental Example 2 except for using the ETL dispersion thus obtained. For the prepared device, electroluminescent properties are measured and the results are shown in Table 3.

### Comparative Example 3

An ETL dispersion including the zinc magnesium oxide prepared in Synthesis Example 2 and a rubidium salt compound in ethanol is prepared.

An electroluminescent device is prepared in the same manner as Experimental Example 2 except that the electron transport layer is prepared in the following manner:

On the light emitting layer, the prepared ETL dispersion is spin-coated and heat-treated for 30 minutes to obtain a first electron transport layer (thickness: 30 nm). For the prepared device, a lifespan of the device is measured and T90 is about 38 hours.

TABLE 3

| | | Maximum | Maximum | |
|---|---|---|---|---|
| | | external | Luminance | |
| | | quantum | (candelas | |
| | | efficiency | per square | |
| | | (EQE) | meter | T90 |
| | electron transport layer | (%) | (cd/m² (nit))) | (hours) |
| Example 1 | CsCl:ZMO | 12.2% | 480,729 | 150 |
| Example 2 | CsCl:Rb:ZMO/ZnO | 11.2% | 431,462 | 160 |
| Example 3 | CsCl:ZMO/ZMO | 14% | 580,000 | 60 |
| Comp. | ZMO | 11.2% | 418,555 | 46 |
| Example 1 | | | | |
| Comp. | ZnO | 6.2% | 312,677 | 30 |
| Example 2 | | | | |
| Example 4 | CsCl:Rb:ZMO | 14.6% | 635,511 | 50 |
| Example 5 | CsCl:Rb:ZMO/Rb:ZMO | 14.8% | 603,329 | 50 |

The results of Table 3, FIG. 7, and FIG. 8 confirm that the electroluminescent devices of Examples 1 to 5 exhibit improved electroluminescent properties and increased life span, in comparison with the device of Comparative Example.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An electroluminescent device comprising:
a first electrode and a second electrode spaced apart from each other;
a light emitting layer disposed between the first electrode and the second electrode; and
an electron transport layer disposed between the light emitting layer and the second electrode,
wherein the light emitting layer comprises a plurality of semiconductor nanoparticles,
wherein the electron transport layer comprises a plurality of zinc oxide nanoparticles, and
wherein the electron transport layer further comprises an alkali metal and a halogen.

2. The electroluminescent device of claim 1, wherein the plurality of semiconductor nanoparticles does not comprise cadmium, lead, mercury, or a combination thereof.

3. The electroluminescent device of claim 1, wherein the electron transport layer is adjacent to the light emitting layer, optionally wherein the electron transport layer is adjacent to the second electrode.

4. The electroluminescent device of claim 1, wherein the zinc oxide nanoparticles comprise Zn₁₋ₓMₓO, wherein M is Mg, Ca, Zr, Co, W, Li, Ti, Y, Al, or a combination thereof, and 0≤x≤0.5.

5. The electroluminescent device of claim 1, wherein an average size of the zinc oxide nanoparticles is greater than or equal to about 1 nanometer and less than or equal to about 10 nanometers.

6. The electroluminescent device of claim 1, wherein
the alkali metal comprises lithium, sodium, potassium, rubidium, cesium, or a combination thereof, and
the halogen comprises chlorine, fluorine, bromine, iodine, or a combination thereof.

7. The electroluminescent device of claim 1, wherein
the alkali metal comprises rubidium, cesium, or a combination thereof, and
the halogen comprises chlorine.

8. The electroluminescent device of claim 1, wherein an amount of the halogen per one mole of the alkali metal is greater than or equal to about 0.3 moles and less than or equal to about 3 moles.

9. The electroluminescent device of claim 1, wherein a thickness of the electron transport layer is greater than or equal to about 5 nanometers and less than or equal to about 70 nanometers.

10. The electroluminescent device of claim 1, wherein
the electron transport layer comprises a first surface facing the light emitting layer and a second surface opposite to the first surface,
the electron transport layer comprises
a first portion in a thickness direction of the electron transport layer, the first portion comprising the first surface,
a second portion in the thickness direction of the electron transport layer, the second portion comprising the second surface, and optionally a third portion between the first portion and the second portion in the thickness direction of the electron transport layer, and
a total amount of the alkali metal and the halogen in the first portion of electron transport layer is greater than a total amount of the alkali metal and the halogen in the second portion of electron transport layer

11. The electroluminescent device of claim 10,
wherein the second portion does not comprise the halogen, or
wherein the first portion comprises an alkali metal that is not present in the second portion.

12. The electroluminescent device of claim 1, wherein
the electron transport layer comprises a first surface facing the light emitting layer and a second surface opposite to the first surface,
the electron transport layer comprises a first layer comprising the first surface and a second layer comprising the second surface, and
the first layer comprises the alkali metal and the halogen.

13. The electroluminescent device of claim 12, wherein
a thickness of the first layer is greater than or equal to about 1 nanometer and less than or equal to about 10 nanometers, and
a thickness of the second layer is greater than or equal to about 4 nanometers and less than or equal to about 40 nanometers.

14. The electroluminescent device of claim 1, wherein in the electron transport layer,
a mole ratio of the halogen to the zinc in the electron transport layer is greater than or equal to about 0.01:1 and less than or equal to about 0.9:1;
a mole ratio of the alkali metal to the zinc in the electron transport layer is greater than or equal to about 0.01:1 and less than or equal to about 0.9:1; or
a mole ratio of the halogen to the zinc in the electron transport layer is greater than or equal to about 0.01:1 and less than or equal to about 0.9:1 and a mole ratio of the alkali metal to the zinc in the electron transport layer is greater than or equal to about 0.01:1 and less than or equal to about 0.9:1.

15. The electroluminescent device of claim 1, wherein in the electron transport layer,
a mole ratio of the halogen to the zinc is greater than or equal to about 0.015:1 and less than or equal to about 0.5:1;
a mole ratio of the alkali metal to the zinc is greater than or equal to about 0.015:1 and less than or equal to about 0.5:1; or
a mole ratio of the halogen to the zinc is greater than or equal to about 0.015:1 and less than or equal to about 0.5:1 and a mole ratio of the alkali metal to the zinc is greater than or equal to about 0.015:1 and less than or equal to about 0.5:1.

16. The electroluminescent device of claim 1, wherein in a graph of external quantum efficiency versus luminance of the electroluminescent device, an external quantum efficiency at a luminance of half the maximum luminance is less than or equal to about 0.7 times of a maximum external quantum efficiency, and wherein a brightness of the electroluminescent device decreases to 50% of an initial brightness of the electroluminescent device after greater than or equal to about 500 hours when operated at a luminance of about 650 candelas per square meter.

17. The electroluminescent device of claim 1, wherein a brightness of the electroluminescent device decreases to 90% of an initial brightness of the electroluminescent device after greater than or equal to about 47 hours when operated at a luminance of about 650 candelas per square meter.

18. The electroluminescent device of claim 1, wherein
the electron transport layer is adjacent to the second electrode, and
an interface roughness between the electron transport layer and the second electrode is greater than or equal to about 5 nanometers and less than or equal to about 100 nanometers.

19. The electroluminescent device of claim 1, wherein the electroluminescent device is configured to emit green light or blue light,
wherein the electroluminescent device exhibits a maximum external quantum efficiency of greater than or equal to about 6%, or
wherein the electroluminescent device exhibits a maximum luminance of greater than or equal to about 60,000 candelas per square meter and less than or equal to about 1,000,000 candelas per square meter.

20. A display device comprising the electroluminescent device of claim 1.

21. The display device of claim 20, wherein the display device comprises a handheld terminal, a monitor, a notebook computer, a television, an electronic display board, a camera, a part for an automatic vehicle.
